(19) United States
(12) Patent Application Publication
(10) Pub. No.: US 2016/0068990 A1
(43) Pub. Date: Mar. 10, 2016

(54) METHODS OF FORMING PEROVSKITE FILMS

(71) Applicant: DREXEL UNIVERSITY, Philadelphia, PA (US)

(72) Inventors: Jonathan E. SPANIER, Bala Cynwyd, PA (US); Andrei AKBASHEU, Philadelphia, PA (US)

(21) Appl. No.: 14/784,598

(22) PCT Filed: Apr. 7, 2014
(86) PCT No.: PCT/US14/33157

§ 371 Date: Oct. 15, 2015

Related U.S. Application Data
(60) Provisional application No. 61/813,554, filed on Apr. 18, 2013.
(60) Provisional application No. 61/880,416, filed on Sep. 20, 2013.

(51) Int. Cl. C30B 1/02; C23C 16/56; C30B 29/30; C30B 1/04; C30B 29/24; C30B 29/32; C23C 16/455; C23C 16/40

(52) U.S. Cl. CPC C30B 1/023; C23C 16/45553; C23C 16/56; C23C 16/40; C30B 1/026; C30B 1/04; C30B 29/24; C30B 29/32; C30B 29/30

(57) ABSTRACT

This disclosure provides methods for forming a perovskite film. Exemplary methods can include the steps of forming an amorphous layer on a substrate disposed in a reaction chamber, covering at least a portion of the amorphous layer with a barrier that at least partially prevents the first metal, the second metal, oxygen atoms, or a combination thereof from being released during annealing and annealing the amorphous layer to form a perovskite film. Formation of the amorphous layer on the substrate disposed in a reaction chamber may be effected by introducing a first compound comprising a first metal; introducing an oxidizing agent; and introducing a second compound comprising a second metal.

### CROSS REFERENCE TO RELATED APPLICATIONS

This application claims the benefit of U.S. Patent Application Nos. 61/813,554, filed Apr. 18, 2013, and 61/880,416, filed Sep. 20, 2013, the contents of which applications are incorporated by reference herein in their entireties for all purposes.

### GOVERNMENT RIGHTS

This invention was made with government support under NSF grant DMR 1124696, and under Materials Science Division of the Army Research Office grant W911NF-08-1-0067. The government has certain rights in this invention.

### TECHNICAL FIELD

This disclosure relates to the fields of atomic layer deposition and growth of perovskite films.

### BACKGROUND

The design of modern electronic and spintronic devices requires materials with unique properties such as high tunneling magnetoresistance and spin filtering efficiency, high-k dielectricity, strong magnetic anisotropy, multiferroicity, and superconductivity. These properties, in turn, demand application of high-vacuum and high-temperature thin-film deposition techniques that can produce heteroepitaxial thin films with exceptional crystalline quality. However, realization of the state-of-the-art in industrially scalable thin film device technologies relies on atomically-controlled thin film preparation routes in which heteroepitaxial thin films of comparably high quality can be attained, but at considerably lower cost.

Although atomic layer deposition (ALD) is a technique for forming conformal coatings of high aspect-ratio structures, there have been difficulties in ALD of simple and complex pervskite oxides, particularly in the growth optimization and an appropriate choice of the precursors with similar ALD temperature windows, high vapor pressure, and the presence of distinct catalytic processes on differently terminated surfaces during deposition. There also exists a long-felt need for epitaxial phase formation of perovskite oxides.

BiFeO₃ is one of the most technologically promising multiferroics with a simple perovskite structure, having ferroelectric order up to TC=1103 K with a large spontaneous polarization (up to ˜150 μC/cm²) found in epitaxial thin films and antiferromagnetism below TN=643 K. It is also attractive among ferroelectric materials for solar energy conversion due to its large photovoltage (exceeding the band gap and up to many tens of volts in thin films) and visible-energy band gap (˜2.7 eV). While high-quality heteroepitaxial BiFeO₃ thin films have been obtained through high-vacuum physical vapor deposition (PLD, MBE, RF sputtering) and metal-organic chemical vapor deposition (MOCVD), an inexpensive low-vacuum surface reaction rate-limited deposition route for obtaining this technologically promising perovskite oxide (or any perovskite oxide) in high-quality heteroepitaxial form, and with applicability for conformal deposition, has not been reported. Thin film BiFeO₃ is considered a difficult material to grow in thin-film form due to Bi volatilization during deposition, which leads to the appearance of parasitic phases in large quantities. Accordingly, there is a long-felt need for a deposition route for obtaining this technologically promising perovskite oxide (or any perovskite oxide) in high-quality heteroepitaxial form, and with applicability for conformal deposition.

### SUMMARY

In one aspect, the present disclosure provides methods for forming perovskite films. The disclosed methods may include forming an amorphous layer on a substrate, covering at least a portion of the amorphous layer with a barrier that at least partially prevents the first metal, the second metal, oxygen atoms, or any combination thereof from being released during annealing, and annealing the amorphous layer to form a perovskite film. Formation of the amorphous layer on the substrate can be effected by introducing a first compound comprising a first metal; introducing an oxidizing agent; and introducing a second compound comprising a second metal so as to form the amorphous layer. The order of these introductions may be varied.

Methods for forming an epitaxial perovskite film by atomic layer deposition are also disclosed. Methods can include the steps of introducing a first compound comprising a first metal, an oxidizing agent, and a second compound comprising a second metal, under sufficient conditions to form a first amorphous film on the first substrate (again, the order of these introductions may be varied); covering substantially all of the first amorphous film with a barrier that prevents the first metal, the second metal, oxygen atoms, or any combination thereof from leaving the film under annealing; and annealing the first amorphous film to produce an epitaxial perovskite film.

In other embodiments, stacked layers of perovskite films may be prepared using variations of the methods described herein.

### BRIEF DESCRIPTION OF THE DRAWINGS

The present application is further understood when read in conjunction with the appended drawings. For the purpose of illustrating the subject matter, there are shown in the drawings exemplary embodiments of the subject matter; however, the presently disclosed subject matter is not limited to the specific methods, devices, and systems disclosed. In addition, the drawings are not necessarily drawn to scale. In the drawings:

FIG. 1 provides a schematic illustration of one embodiment of an atomic layer deposition (ALD) process. In this example, BiFeO₃:Bi precursor molecules (Bi(mmp)₃) are delivered by a vapor pulse adsorb on the surface of the Bi—Fe—O amorphous layer producing a Bi—O layer; molecules are then oxidized by ozone (O₃). Following this, the sample is exposed to a vapor pulse of Fe(C₅H₅)₂ producing an Fe—O layer, subsequently followed by oxidation using O₃. The process of alternating pulses of selected number and duration is optimized to produce the desired post-anneal stoichiometry and structural quality in the resulting film (not shown).

FIG. 2(A) shows XRD patterns (2θ/ω scans) of the as-deposited films grown at 300° C., 350° C. and annealed at 700° C. for 3 min.; (FIG. 2(B)) XRR patterns of the films grown at 300° C. and 350° C. showing a decrease in the surface quality upon the increase of the growth temperature; the growth rate is independent of temperature (FIG. 2(C)) and changes linearly with a number of cycles (FIG. 2(D));

FIG. 3(A) shows X-ray reflectivity of typical as-deposited Bi—Fe—O and individual constituent oxide thin films deposited on SiO₂/Si, confirming roughness on the atomic scale; FIG. 3(B) shows 2θ/ω scans of a typical BiFeO₃ thin film grown on SrTiO₃ obtained by annealed in air at 700° C.; inset: rocking curves (ω scans) of the (001) reflection of the BiFeO₃ thin film and the SrTiO₃ substrate show a high epitaxial quality of prepared perovskite film; FIG. 3(C) shows 20/w scans BiFeO₃ crystallization in the form of 30-50 nm-thick epitaxial thin films after the annealing of amorphous Bi—Fe—O samples at different temperatures;

FIG. 4(A) shows a low-magnification TEM image of the BiFeO₃ thin film grown on (001)-oriented SrTiO₃; FIGS. 4(B-C) show selected-area electron diffraction of the BiFeO₃ film and SrTiO₃ substrate; FIGS. 4D-E) show high-resolution TEM image of the interface between BiFeO₃ and SrTiO₃ and corresponding Fourier-filtered image showing the absence of misfit dislocations at the interface;

FIG. 5 shows a representative hysteresis behavior of ferroelectric piezoelectric (FIG. 5(A)) amplitude and (FIG. 5(B)) phase in an ALD-grown heteroepitaxial BiFeO₃ (001) thin film grown on Nb:SrTiO₃ (001); (FIG. 5(C)) representative topographic height and (FIG. 5(D)) piezoresponse force microscopy (PFM) amplitude contrast images of the BiFeO₃/Nb:SrTiO₃ film surface exhibiting patterned domains following successive writing of two square-shaped regions (one within the other) written using Vₜᵢₚ=±10V, and read using a tip voltage V_{ac} of 200 mV. Rectangular islands of sillenite phase are not seen to exhibit switching for the voltages applied, but do not disrupt the domain imaging;

FIGS. 6(A-B) show SEM images of the sillenite Bi₂₆₋ₓFeₓO_{40-y} phase crystallized on the surface of the BiFeO₃ film with Bi:Fe>1; FIGS. 6(C-F) show EDS maps of chemical elements taken from the region shown in (b);

FIG. 7(A) shows an SEM image of the morphology. Inset and FIG. 7(B) show an XRD pattern of the annealed BiFeO₃ thin film (˜50 nm thick);

FIG. 8 shows XRD traces showing simultaneous growth of BiFeO₃ (Bi:Fe>1) on SiO₂/Si (top) and on SrTiO₃(001) substrates. Perovskite BiFeO₃ oriented growth is observed on both substrates. The asterisks denote the unknown phase crystallized on SiO₂/Si; and

FIG. 9(A) shows a sillenite cube on top of BiFeO₃ and an unknown phase; FIG. 9(B) shows a high-resolution image of the unknown phase; FIG. 9(C) shows the growth of the unknown phase on SrTiO₃;

FIG. 10 shows piezoresponse data (left) and corresponding phase (right) collected from a BiFeO₃(001)/Nb:SrTiO₃ sample, providing further confirmation of ferroelectric switching.

FIG. 11 shows a thermogravimetric analysis for Bi(ac)3:tris(acetate)bismuth, or bismuth (III) acetate synthesized this in this work. Sample run under argon (100 mL/min on SDT Q600 V20.9 Build 20 DSC-TGA analyzer.

FIGS. 12(A-C) shows the magnetic characteristics of field-cooled (FC) and zero-field-cooled (ZFC) M(T) in ALD-grown BiFeO₃/SrTiO₃ (001). Notable changes at T², T¹, and T* correspond to low-temperature dielectric anomalies normally found in bulk BiFeO₃ at 55K and 215K. See, e.g., S.A.T. Redfern, J. Phys. Cond. Mat. 20, 452205 (2008). The change in sign of M (at T¹) may be attributable to a spin-reorientation transition.

FIG. 13 shows magnetic susceptibility data for a film of single-crystal heteroepitaxial film stabilized monoclinic/tetragonal modified BiFeO₃ formed according methods described herein (deposition and subsequent annealing). These data are generally consistent with films of high atomic structural quality produced using other more expensive methods. Note the absence of net magnetic moment.

### DETAILED DESCRIPTION OF ILLUSTRATIVE EMBODIMENTS

The present invention may be understood more readily by reference to the following description taken in connection with the accompanying Figures and Examples, all of which form a part of this disclosure. It is to be understood that this invention is not limited to the specific products, methods, conditions or parameters described and/or shown herein, and that the terminology used herein is for the purpose of describing particular embodiments by way of example only and is not intended to be limiting of any claimed invention. Similarly, unless specifically otherwise stated, any description as to a possible mechanism or mode of action or reason for improvement is meant to be illustrative only, and the invention herein is not to be constrained by the correctness or incorrectness of any such suggested mechanism or mode of action or reason for improvement. Throughout this text, it is recognized that the descriptions refer both to the features and methods of making and using perovskite films, as well as the perovskite films themselves, and vice versa.

In the present disclosure the singular forms “a,” “an,” and “the” include the plural reference, and reference to a particular numerical value includes at least that particular value, unless the context clearly indicates otherwise. Thus, for example, a reference to “a material” is a reference to at least one of such materials and equivalents thereof known to those skilled in the art, and so forth.

When a value is expressed as an approximation by use of the descriptor “about,” it will be understood that the particular value forms another embodiment. In general, use of the term “about” indicates approximations that can vary depending on the desired properties sought to be obtained by the disclosed subject matter and is to be interpreted in the specific context in which it is used, based on its function. The person skilled in the art will be able to interpret this as a matter of routine. In some cases, the number of significant figures used for a particular value may be one non-limiting method of determining the extent of the word “about.” In other cases, the gradations used in a series of values may be used to determine the intended range available to the term “about” for each value. Where present, all ranges are inclusive and combinable. That is, references to values stated in ranges include every value within that range.

It is to be appreciated that certain features of the invention which are, for clarity, described herein in the context of separate embodiments, may also be provided in combination in a single embodiment. That is, unless obviously incompatible or specifically excluded, each individual embodiment is deemed to be combinable with any other embodiment(s) and such a combination is considered to be another embodiment. Conversely, various features of the invention that are, for brevity, described in the context of a single embodiment, may also be provided separately or in any sub-combination. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation. Finally, while an embodiment may be described as part of a series of steps or part of a more general structure, each said step may also be considered an independent embodiment in itself.

The transitional terms “comprising,” “consisting essentially of,” and “consisting” are intended to connote their generally in accepted meanings in the patent vernacular; that is, (i) “comprising,” which is synonymous with “including,” “containing,” or “characterized by,” is inclusive or open-ended and does not exclude additional, unrecited elements or method steps; (ii) “consisting of” excludes any element, step, or ingredient not specified in the claim; and (iii) “consisting essentially of” limits the scope of a claim to the specified materials or steps “and those that do not materially affect the basic and novel characteristic(s)” of the claimed invention. Embodiments described in terms of the phrase “comprising” (or its equivalents), also provide, as embodiments, those which are independently described in terms of “consisting of” and “consisting essentially of” For those embodiments provided in terms of “consisting essentially of,” the basic and novel characteristic(s) is the ability to form of nearly pure perovskite films using atomic layer deposition and the structures which results therefrom.

When a list is presented, unless stated otherwise, it is to be understood that each individual element of that list, and every combination of that list, is a separate embodiment. For example, a list of embodiments presented as “A, B, or C” is to be interpreted as including the embodiments, “A,” “B,” “C,” “A or B,” “A or C,” “B or C,” or “A, B, or C.”

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, representative illustrative methods and materials are described herein.

Methods for forming perovskite films and stacked layers of perovskite films are disclosed. While many of the specific descriptions provided herein relate to BiFeO₃, the methods are more generally applicable to other perovskite materials. Accordingly, references to BiFeO₃ should be considered specific to this material as well as representative of other perovskite materials. As used herein, perovskite refers to any material having an ideal perovskite crystal structure or a slightly distorted perovskite structure. The term “ideal perovskite crystal structure” is well understood by those skilled in the art as comprising any material with the same type of crystal structure as calcium titanium oxide (CaTiO₃), known as the perovskite structure, or XIIA²⁺VIB⁴⁺X²⁻₃ with the oxygen in the face centers. While, in preferred embodiments of the present invention, the perovskite structures comprise, or the methods of producing them yield, substantially defect-free materials. However, the presence of dopants, inclusions of other phases, or inclusions should not be interpreted as distracting from this definition.

Examples of perovskite materials include ferrites, niobates, certain silicates, titanates, zirconates, and mixtures thereof. Non-limiting examples of such materials include BaTiO₃, BiFeO₃, CaTiO₃, MgSiO₃, PbTiO₃, PbZrO₃, SrTiO₃, and solid solutions thereof (e.g., Pb(Mn_{1/3}Nb_{2/3})O₃, Pb(Zn_{1/3}Nb_{2/3})O₃, Pb/ZrTiO₃, (K,Ba)(Ni,Nb)O_{3-δ}, where δ specifies O vacancy concentration), including those compositions in which the A and B sites may each comprise one or more metals—e.g. so-called double perovskites (AA′BB′O₃ such as Bi₂FeCrO₆, Bi₂NiMnO₆, Pb₂CoMoO₆, LaBiMnCrO₆, (Baₓ,Sr₍₁₋ₓ₎)TiO₃, and the like.

The term “stacked layers of perovskite films” refers to at least two layers of perovskite films, formed coplanar with one another (e.g., one on top of another), either by co-annealing coplanar layers of sequentially deposited amorphous films (as described herein) or by the sequential deposition and annealing of such amorphous films to form the layered perovskite structures. Each layer may be compositionally the same or different (either by virtue of the perovskite itself or the presence or absence of dopants) from the preceding layer. Each layer may comprise different metals, dopant, or perovskite structures than the preceding layer. Each layer may comprise the same metals but in different ratios/stoichiometries than the preceding layer. In the latter case, such a series of layers may provide a gradient structure of structurally related materials. In some embodiments, the layers may form alternating structures of two same or differing perovskite compositions. In other embodiments, the alternating structures may vary periodically or non-periodically. Non-limiting examples of such layered structures include those represented by:
A¹A²B¹B²O_{(3-delta)}, where 0≦delta≦3.
A¹B¹O₃/A²B²O₃
A¹B¹O₃/A¹B²O₃
A¹B¹O₃/A²B¹O₃
A¹B¹O₃/A²B²O₃/A¹B¹O₃/A²B²O₃/A¹B¹O₃/A²B²O₃, . . .
A¹B¹O₃/A¹B²O₃/A¹B¹O₃/A¹B²O₃/A¹B¹O₃/A¹B²O₃ . . . .
A¹B¹O₃/A²B¹O₃/A¹B¹O₃/A²B¹O₃/A¹B¹O₃/A²B¹O₃ . . . .
A¹B¹O₃/A²B²O₃/A¹B¹O₃/A¹B²O₃ . . .
A¹B¹O₃ . . . A¹ₓA²₍₁₋ₓ₎B¹_{y}B²_{(1-y)} . . . A²B²O₃ (gradient in composition)
   where A¹ and A² refer to two different A site elements, B¹ and B² to two different B site elements, and so forth. In some cases, O₃ may also be replaced by O_(3-delta), where 3-delta provides for holes in the structure.

The perovskite layers may also be interlayered with binary oxides, for example:
A¹B¹O₃/A¹O/A¹B¹O₃/A¹O . . .
A¹B¹O₃//A²O/A¹B¹O₃/A²O . . .
A¹B¹O₃/B¹O/A¹B¹O₃/B¹O . . .
A¹B¹O₃/A¹O/A¹B¹O₃/B¹O . . .
A¹B¹O₃/A¹O/A¹B¹O₃/B¹O . . .

More specifically, layered structures of the following compositions are available by the disclosed methods:
(Baₓ,Sr₍₁₋ₓ₎ TiO₃, single layer or
BaTiO₃ . . . (Baₓ,Sr₍₁₋ₓ₎)TiO₃ . . . SrTiO₃ (or reverse order)
(Baₓ,Sr₍₁₋ₓ₎)TiO₃ . . . (Ba_{y},Sr_{(1-y)})TiO₃ (or reverse order)
or
(K,Ba)(Ni,Nb)O_{(3-delta)} where 0≦delta≦3; or
KNbO₃₍₁₋ₓ₎—Ba(Ni,Nb)O_{(3-delta)(x)} where 0≦x≦0.5 and 0≦delta≦3.

The perovskite films described herein can be formed on a substrate that can be any solid material, including metals, metal oxide, and combinations thereof. The substrates may be chosen so as to be structurally and compositionally the same (i.e., homoepitaxial), similar, or compositionally different (i.e., heteroepitaxial) than the target perovskite crystal(s). It is preferred, but not necessary, that the substrate comprise a material having the same or similar lattice parameters, relative to the target perovskite crystal(s). This feature may be relaxed for polycrystalline perovskites, but for single crystal materials, it is preferred that the difference between the in-plane lattice parameters of the substrate and that of the target crystal be less than 5%, less than 4%, less than 3%, less than 2%, or less than 1%, most preferably less than 0.5% or zero. Lower lattice mismatch provides fewer dislocations at the interface, and in some cases, the compositions may comprise a crystal-substrate interface that is dislocation free. Similarly, for single crystal materials, it is preferred that the difference between the coefficient of thermal expansion of the substrate and that of the crystal be less than 5%, less than 4%, less than 3%, less than 2%, or less than 1%, most preferably less than 0.5% or zero, so as to minimize any strain which may develop during cooling after the annealing step. Exemplary substrates include ceria (CeO₂), diamond, surface-oxidized silicon, silica, sapphire, MgO, MgAl₂O₄ (spinel), YSZ (Y-doped ZrO₂), SrLaAlO₄; and perovskites, such as ABO₃ (where A=Li, K, Mg, Ag, Ca, Sr, Ba, rare earths, Sc, Y, In, Pb, and Bi; and B=Cu, Zn, Ga, Ge, Al, Sc, Ti, V, Cr, Mn, Fe, Co, Ni, Zr, Nb, Ir, La, Bi) and their doped phases, including SrTiO₃, LaTiO₃, LaAlO₃, DyScO₃, GdScO₃, KTaO₃, (La,Sr)(Al,Ta)O₃, or the like; or combinations thereof.

In some embodiments, a first perovskite layer may be applied to a non-perovskite surface (e.g., metals or metalloids such as a silicon or oxidized silicon substrate), after which one or more subsequent perovskite layers may be deposited and formed. In but one, non-limiting, example, an epitaxial SrTiO₃ is first prepared by the formation and annealing of the SrTiO₃ precursor layer onto a silicon substrate using the ALD methods described herein, followed by subsequent layering of BiFeO₃ or other perovskite layers upon the first-formed SrTiO₃ layer, again, using the methods described herein.

Substrates may also be planar or substantially planar (i.e., allowing for the formation of single crystal films) or otherwise shaped. In the latter case, the substrate may contain features having nano-, micro-, or millimeter-dimensions, or some combination thereof. The annealed films which form on such features may be single or poly-crystalline, depending on the level of specific dimensions, annealing conditions, or both dimensions and annealing conditions (high structural angularity and fast annealing favoring formation of polycrystalline phases).

The perovskite films may also be doped with materials which effect some property of the final crystal(s), using methods described herein, including the use of volatile metals, metalloids, or other materials intended as a dopant (see infra)

A perovskite film can be formed, optionally in a reaction chamber, including a substrate by introducing a first compound, an oxidizing agent, and a second compound into the reaction chamber. The first and second compounds and the oxidizing agent can be introduced sequentially in any order or simultaneously. In some embodiments the first or second compound is introduced followed by introduction of the oxidizing agent before the other of the first or second compound is introduced. It should be understood that the first and second compounds and oxidizing agent may be introduced in any order. The first and second compounds and oxidizing agent may be introduced in an alternating fashion, e.g., first compound-oxidizing agent, second compound-oxidizing agent, first compound-oxidizing agent, and so on. The user may perform several cycles of introducing the first or second compound and oxidizer followed by several cycles of introducing the other compound and oxidizer.

Certain embodiments provide methods for forming perovskite film by atomic layer deposition, each method comprising:
(a) introducing at least one first compound comprising a first metal, an oxidizing agent, and at least one second compound comprising a second metal so as to form an amorphous layer comprising the first and second metals and an oxidizing agent on a first substrate; then
(b) covering at least a portion of the amorphous layer with a barrier that at least partially prevents the first metal, the second metal, oxygen atoms, or any combination thereof from being released during annealing; and then
(c) annealing the amorphous layer to form a perovskite film.

Other embodiments provide methods, each method comprising:
(a) introducing at least one first compound comprising a first metal, an oxidizing agent, and at least one second compound comprising a second metal onto a substrate, wherein the introduction is performed under sufficient conditions to form a first amorphous film comprising the first and second metals and oxidizing agent on the first substrate;
(b) covering substantially all of the first amorphous film with a barrier that prevents the first or second metal or any combination thereof from leaving the film under annealing; and
(c) annealing the first amorphous film to produce an epitaxial perovskite film. The epitaxial perovskite film may be heteroepitaxial, single or polycrystalline, or a combination thereof.

In some of these embodiments, the barrier comprises a second amorphous layer comprising the first and second metals and oxidizing agent. In other embodiments, the barrier further comprises a second substrate. In the former embodiments, the covering step can comprise contacting the second amorphous layer to the amorphous layer to form an amorphous film comprising the first and second metals and oxidizing agent sandwiched between a first and second substrate. In some embodiments, the barrier is used to cover only a portion of the amorphous layer; in other embodiments, it is used to cover substantially all of the amorphous layer. The skilled artisan will appreciate that the terms “at least a portion” and “substantially all” are terms of degree; unless otherwise stated, the term “at least a portion” refers to at least 10% of the total area of the amorphous layer, and “substantially all” refers to at least 90% of the total area of the amorphous layer. Other embodiments provide that this coverage can range from about 5%, about 10%, about 15%, about 20%, about 25%, about 30%, about 35%, about 40%, about 45%, or about 50% to about 95%, about 90%, about 85%, about 80%, about 75%, about 70%, about 65%, about 60%, about 55%, about 50% or practically all of the amorphous layer.

Stacked layers may also be prepared by repeating the processes described. That is, additional embodiments provide methods, wherein step (a) as described above is repeated to produce at least two amorphous layers prior to effecting steps (b) and (c), wherein each application of step (a) introduces a different first compound and a second compound than the preceding step, or a different ratio of first compound and a second compound than the preceding step, such that each of the least two amorphous layers are compositionally different than the preceding layer.

Still further methods include those wherein steps (a) through (c) as described above are repeated to produce at least two stacked perovskite films, wherein each application of steps (a) through (c) introduces a different first compound and a second compound than the preceding step, or a different ratio of first compound and a second compound than the preceding step, such that each of the least two perovskite are compositionally different than the preceding film. Each of the at least two perovskite films may have a different crystalline or polycrystalline structure than the preceding layer.

The first compound, second compound, and oxidizing agent can each independently be in a vapor phase or introduced into the reaction chamber by a carrier gas.

While the first and second compounds and first and second metals are generally described as each comprising single materials (e.g., first compound is a single material comprising a single metal), it should be appreciated that the methods described herein also provide that the “first compound” or “first metal” may refer to more than one compound or metal, providing that the associated metals or metalloids occupies a similar A lattice position in the general ABO₃ perovskite structure. Similarly, the “second compound” or “second metal” may refer to more than one compound or metal, providing that the associated metals or metalloids occupies a similar B lattice position in the general ABO₃ perovskite structure. Using such mixed compounds, it is possible to prepare the double

The first compound and second compound can comprise, respectively, a first metal, such as Ba, Bi, Ca, Mg, Pb, Sb, Sr, or a combination thereof; and a second metal, such as Fe, In, Mg, Nb, Si, Ti, Zn, Zr, or a combination thereof. The first and/or second compounds can be a metal bound to one or more organic ligands and may also be referred to as metal precursors or precursors. For those materials being added in a gas or vapor phase, it should be appreciated that the ligands around the metals should provide for sufficient volatility.

Exemplary ligands include optionally substituted acetylacetonates, mono-, di-, or tri-alkoxides, alkoxyalcohols, alkoxyamines, carboxylates, cyclopentadienyl, heptanedionates, phenanthrolines, arenes (e.g., cyclopentadienyls), or the such. In the case of antimony or bismuth, substituted phenyl ligands may also be conveniently used, either alone (e.g., Bi(phenyl)₃, Sb(phenyl)₃, tris(2-methoxyphenyl)bismuthine) or in combination with other ligands (e.g., bis(acetato-O)triphenylbismuth(V)). Other exemplary bismuth precursors include Bi(ac)₃:tris(acetate) bismuth, bismuth (III) carboxylates (e.g., bismuth neodecanoate or bismuth(III) citrate); or Bi(thd)₃:tris(tris(2,2,6,6-tetramethyl-3,5-heptanedionate)) bismuth (III). Other materials, such as those described in Marko Vehkamäki, et al., “Bismuth precursors for atomic layer deposition of bismuth-containing oxide films,” J. Mater. Chem., 2004, 14, 3191-3197, which is incorporated by reference herein, may also be useful in this application.

Non-limiting examples of precursors for depositing iron include Fe(acac)₃:tris(acetylacetonate) iron (III); Fe(thd)₃:tris(2,2,6,6-tetramethyl-3,5-heptanedionate)iron(III); Fe(O-tBu)₃:iron(III) tert-butoxide; substituted ferrocenes, for example Fe(2,4-C₇H₁₁)₂:Bis(2,4-dimethylpentadienyl)iron.

Other exemplary potential precursors for preparing A-site metals or dopants for Ag, Ba, Bi, Ca, Na, Sr, rare earths (La to Lu), Y, K, Pb, Pr include (a) for M=Sr,Ca,Ba:M(thd)₂, M(ac)₂ (metal(II) acetate), M(iPrCp)₂ (bis(iso-propylcyclopentadienyl) metal), M(MeCp)₂(bis(methylcyclopentadienyl) metal); (b) for M=rare earth elements (La—Lu) and Y:M(OC(CH₃)₂CH(CH₃)₂)₃ (tris(2,3-dimethyl-2-butoxy)metal(III)), M(thd)₃, M(iPrCp)₃ (tris(iso-propylcyclopentadienyl) metal); (c) for M=K, K(thd), K(tert-butoxide); and (d) for M=Pb:Pb(DMAMP)₂ (bis(3-N,N-dimethyl-2-methyl-2-propanoxide) lead).

Other exemplary potential precursors for preparing B-site metals or dopants for Al, Bi, Ce, Co, Cr, Fe, Ga, Hf, Ho, Ir, Mg, Mn, Mo, Nb, Ni, Pd, Pt, Rb, Ru, Sc, Ta, Ti, V, W, Zn, Zr include (a) Co(thd)₂; (b) Mn(thd)3; (c) Ga(acac)3, Ga2(N(CH3)2)6, and trimethylgallium; (d) Ni(MeCp)₂ (bis(methylcyclopentadienyl) nickel), and Ni(thd)₂; (e) Nb(OEt)₅ (Et=ethyl), Nb(NEt₂)₃ ((tert-butylimido)tris(diethylamido)niobium), Nb(OtBu)₃ ((1,1-dimethylpropylimido); and tris(tert-butoxide)niobium); (f) TiCl₄, Ti(NMe₂)2(OiPr)₂ (titanium bis(dimethylamide)bis(isopropoxide)), Ti[OCH(CH₃)₂]₄ (titanium isopropoxide); (g) VOCl₃ (vanadium oxychloride), vanadium tri(isopropoxide), VO(acac)₂ (vanadium oxyacetylacetonate); and (h) (MeCp)₂ZrMe₂ (Me=methyl, Cp=cyclopentadienyl), ZrI₄ (ziconium tetraiodide), and (Tetrakisethylmethylamino)zirconium.

In the preparation of BiFeO₃, one such exemplary first compound is Bi(mmp)₃ (tris(1-methoxy-2-methyl-2-propoxy)bismuth). One such exemplary second compound is Fe(Cp)₂ (Fe(C₅H₅)₂; ferrocene).

Suitable oxidizing agents may include—but are not limited to—ozone, water, oxygen, hydrogen peroxide, oxides of nitrogen, halide-oxygen compounds, peracids, alcohols, alkoxides, oxygen-containing radicals, oxygen-containing plasma, and mixtures thereof. As used herein, metal can refer to alkaline earth metals, transition metals, or metalloids, or other elements that is capable of forming or participating in a perovskite crystal structure.

Introduction of the first compound, the second compound, and the oxidizing agent into the reaction chamber can be performed under conditions sufficient to form an amorphous layer that can include the first metal, the second metal and oxygen. The amorphous film can have an atomic ratio of first metal to second metal of about the desired stoichiometric ratio of the perovskite crystal to be formed. In these methods, some consideration may also be made for the relative volatilities of the first and second metal precursors or oxides. For example, when the target perovskite has a ratio of the first to second metal of 1:1 (e.g., BiFeO₃), the amorphous film can have an atomic ratio of first metal to second metal in a range of from about 1.3:1 to about 1:1, or from about 1.2:1 to about 1:1, or from about 1.1:1 to about 1:1, or from about 1 to about 1:1.3, or from about 1:1 to about 1:1.2, or from about 1:1 to about 1:1.1, depending on the relative volatilities of the metal components. Or the the amorphous film can have an atomic ratio of first metal to second metal of about 1:1. Determination of the optimum or appropriate ratios for a given system can be achieved by routine, and not undue, experimentation. More complicated mixed oxides could be prepared similarly.

Conditions sufficient to form an amorphous layer (also referred to herein as a film) include conditions appropriate for performing atomic layer deposition of the first compound, the second compound, and the oxidizing agent. As one non-limiting example, the temperature at which the first compound, second compound, or oxidizing agent are introduced can be a temperature that is sufficient to evaporate the first compound, second compound, or oxidizing agent, respectively, but not so great as to result in decomposition of the first compound, second compound, or oxidizing agent, respectively. The substrate can be heated to a temperature sufficient to form growth of the film, such as a range of from about 100° C. to about 500° C., from about 150° C. to about 300° C. or about 250° C. The steps of introducing the first compound, introducing the second compound and oxidizing can, as explained elsewhere herein, each be repeated any number of times to achieve the desired growth rate of individual components of the amorphous layer or to achieve a desired thickness of the amorphous layer. For example, where the first component grows at a greater rate than the second component, introduction of the first compound may be repeated a greater number of times than introduction of the second component.

Deposition of the amorphous layers are generally achieved under vacuum conditions, perhaps described as “soft-vacuum” conditions, where the total operating pressure when using organometallic precursors is a range of about 1 to about 1000 millitorr. In certain embodiments, the depositions may be conducted at pressures in a range of from about 1 to about 10 millitorr, from about 10 to about 50 millitorr, from about 50 to about 100 millitorr, from about 100 to about 250 millitorr, from about 250 to about 500 millitorr, from about 500 to about 1000 millitorr, or some combination thereof. Oxygen may be introduced at higher pressures, for example 1 to about 10 torr, from about 10 to about 50 torr, from about 50 to about 100 torr, from about 100 to about 250 torr, from about 250 to about 500 torr, or some combination thereof. Preferred conditions, at least for the Bi(mmp)₃/Fe(Cp)₂ system appears to be in a pressure range of from about 7 millitorr to about 75 millitorr (about 0.01 to about 0.1 millibar; the pressure rises to 380 torr (0.5 atm) during the oxygen pulse and up to 750 millitorr (1 mbar) in a non-closed, pumped-through operation during the precursor pulses.

It should also be appreciated that the deposition of the various precursors (including optional dopants) may be done such that the final amorphous layer or final crystalline perovskite is compositionally homogeneous or heterogeneous. “Compositionally heterogeneous” includes those circumstances where the compositions vary (either step-wise or continuously) at different lateral positions in a given layer, at different depths within a given layer, or at different lateral and depth positions within a given layer. For example, a given layer of BiFeO₃ may be iron-rich (relative to bismuth) at or near the substrate, and iron-deficient (relative to bismuth) at or near the exposed perovskite surface, or vice versa.

As described elsewhere herein, it should also be appreciated that, while the present disclosure speaks in terms of individual perovskite films, the same or similar methods may be employed to provide multiple perovskite, wherein each perovskite layer is the same or different as one another, and where one perovskite layer is immediately adjacent to another or are separated by different materials (e.g., metals, metalloids, or non-perovskite inorganic materials).

In the specific (and representative) case where the first compound is Bi(mmp)₃ and the second compound is Fe(Cp)₂, each material may be introduced more than one time, and the a different number of times than the other; e.g., the Fe(Cp)₂ may be introduced three to five times as many times or for three to five times as long as the Bi(mmp)₃. The reaction chamber may be evacuated of excess reactant or compound that is not bound to the substrate or otherwise part of the amorphous layer in between introducing steps.

A barrier can be used to cover all or a portion of the layer formed on the substrate. The barrier can prevent or at least partially prevent the first metal, the second metal, oxygen atoms, or any combination thereof from being released from the layer. For example, a first metal can be susceptible to volatilization and escape from the film, such as during annealing. The use of a barrier to cap the film can substantially maintain the amount of first metal in the film. It should be understood that the barrier may be formed in place atop the film and may also be formed elsewhere and then contacted to the film.

Examples of suitable barriers include those comprising compositions having the same or different compositions as the amorphous material or the target perovskite. In one variation of this, two formed amorphous layers, having the same or similar compositions, may be placed face-to-face against one another, in a sandwich-like arrangement. Alternatively, the barrier may comprise a material, compositionally different than the amorphous or target crystal perovskite, for example silica. While not intending to be bound by the correctness or incorrectness of any particular theory, it appears that each of these arrangements is useful in reducing or practically eliminating volatilization and loss of the more volatile material(s). Again, adjustment to the ratios of the components in the amorphous layers may be useful in compensating for even low losses associated with this technique. In other embodiments, an additional layer, such as a second amorphous layer, and a second substrate placed on the amorphous layer such as silica, surface-oxidized silicon, or a perovskite like SrTiO₃. The amorphous layer can be covered by a barrier comprising a second amorphous layer by introducing additional amounts of first compound, second compound, and oxidizing agent into the reaction chamber.

A barrier can comprise the same first metal and second metal as the first amorphous layer or can comprise a different first metal, second metal or both. Alternatively, a barrier comprising a second amorphous film can be separately formed through atomic layer deposition of one or more metal precursor compounds onto a second substrate in a reaction chamber, and the barrier can be used to cover the first amorphous layer by contacting the second amorphous layer of the barrier with the first amorphous layer. The barrier may suitably surmount the entire exposed area of the film, although this is not a requirement.

After a barrier has been provided on the amorphous layer, the amorphous layer is suitably annealed to form a crystalline structure, e.g., the perovskite film. Annealing can be performed at a temperature in a range of from about 100° C. to about 900° C., from about 300° C. to about 800° C., or from about 600° C. to about 740° C. The annealing can be accomplished by placing the amorphous material directly into a preheated thermal chamber at the temperature of interest, or in a furnace capable of ramping the temperatures. In the latter case, the temperature can be increased in a range of from about 1° C. per minute to about 20° C. per minute, from about 2° C. per minute to about 10° C. per minute, or from about 3° C. per minute to about 5° C. per minute, or using a more rapid thermal annealing process, such as from about 5° C. to about 100° C. per minute, or even 5° C. to about 100° C. per second. Such temperature increase can be an average increase or a step-wise increase.

The annealing may be achieved by joule, radiant, convective, pulsed or steady state laser, or other heating means. Annealing may also be done in the presence or absence of a poling electric field. Such poling conditions are known in the art for a given perovskite composition. These techniques may be employed statically or manipulated to achieve controlled crystallization in selected regions with minimal heat transfer to the substrate. The ability to couple the present ALD deposition methods with such directed energy annealing to provide a single-crystal film would represent another novel aspect of the present invention(s).

The crystalline structure or film that is formed by annealing the amorphous layer can be epitaxial. In some embodiments, if grown on a substrate that is a different crystal than the crystal formed by annealing, can be heteroepitaxial. For example, the crystalline structure formed from the amorphous layer can be perovskite in form. The crystalline structure can be heteroepitaxial.

To this point, the invention has been described in terms of methods of producing superior single or polycrystalline materials, but it should be appreciated that the single and polycrystalline materials, and products which incorporate these materials, are also considered to be within the scope of the invention. For example, these methods and materials may be applied to ferroelectric photovoltaics, piezoelectric sensors and motion devices, regenerative catalysts and photocatalysts, and superconductive devices.

The following listing of embodiments is intended to complement, rather than displace or supersede, the previous descriptions.

### Embodiment 1

A method for forming a perovskite film by atomic layer deposition, said method comprising:
(d) introducing at least one first compound comprising a first metal, an oxidizing agent, and at least one second compound comprising a second metal so as to form an amorphous layer comprising the first and second metals and an oxidizing agent on a first substrate; then
(e) covering at least a portion of the amorphous layer with a barrier that at least partially prevents the first metal, the second metal, oxygen atoms, or any combination thereof from being released during annealing; and then
(f) annealing the amorphous layer to form a perovskite film.

### Embodiment 2

The method Embodiment 1, the barrier comprising a second amorphous layer comprising the first and second metals and oxidizing agent.

### Embodiment 3

The method of Embodiment 1 or 2, wherein the annealing forms a single-crystalline perovskite film.

### Embodiment 4

The method of any one of Embodiments 1 to 3, wherein the barrier further comprises a second substrate.

### Embodiment 5

The method of Embodiment 3, wherein the covering step comprises contacting the second amorphous layer to the amorphous layer to form an amorphous film comprising the first and second metals and oxidizing agent sandwiched between a first and second substrate.

### Embodiment 6

The method of any one of Embodiments 1 to 5, the method comprising: (a) introducing at least one first compound comprising a first metal, an oxidizing agent, and at least one second compound comprising a second metal onto a substrate, wherein the introduction is performed under sufficient conditions to form a first amorphous film comprising the first and second metals and oxidizing agent on the first substrate; (b) covering substantially all of the first amorphous film with a barrier that prevents the first or second metal or any combination thereof from leaving the film under annealing; and (c) annealing the first amorphous film to produce an epitaxial perovskite film.

### Embodiment 7

The method of Embodiment 1 or 6, wherein annealing the first amorphous film produces a hetero-epitaxial perovskite film.

### Embodiment 8

The method of Embodiment 1 or 6, wherein annealing the first amorphous film produces a single-crystalline hetero-epitaxial perovskite film.

### Embodiment 9

The method of any one of Embodiments 1 to 8, wherein the barrier used in the covering step comprises a second amorphous film comprising the first metal, the second metal, and oxygen disposed on a second substrate.

### Embodiment 10

The method of Embodiment 9, wherein covering substantially all of the first amorphous film is performed by contacting the second amorphous film of the barrier to the first amorphous film.

### Embodiment 11

The method of any one of Embodiments 1 to 10, wherein step (a) is repeated to produce at least two amorphous layers prior to effecting steps (b) and (c), wherein each application of step (a) introduces a different first compound and a second compound than the preceding step, or a different ratio of first compound and a second compound than the preceding step, such that each of the least two amorphous layers are compositionally different than the preceding layer.

### Embodiment 12

The method of Embodiment 11, wherein each of the at least two amorphous layers comprise the same first and second metals in differing proportions relative to the preceding film.

### Embodiment 13

The method of any one of Embodiments 1 to 10, wherein steps (a) through (c) are repeated to produce at least two stacked perovskite films, wherein each application of steps (a) through (c) introduces a different first compound and a second compound than the preceding step, or a different ratio of first compound and a second compound than the preceding step, such that each of the least two perovskite are compositionally different than the preceding film.

### Embodiment 14

The method of Embodiment 13, wherein each of the at least two perovskite films comprise the same first and second metals in differing proportions relative to the preceding film.

### Embodiment 15

The method of Embodiment 13 or 14, wherein each of the at least two perovskite films have a different crystalline or polycrystalline structure than the preceding layer.

### Embodiment 16

The method of any one of Embodiments 1 to 15, wherein at least one of the first metals is Bi.

### Embodiment 17

The method of Embodiment 16, wherein the first compound is (tris(1-methoxy-2-methyl-2-propoxy)bismuth) [Bi(mmp)₃], triphenylbismuth, tris(tris(2,2,6,6-tetramethyl-3,5-heptanedionate))bismuth (III) [Bi(thd)₃], or Bi(acetate)₃.

### Embodiment 18

The method of any one of Embodiments 1 to 17, wherein at least one of the second metals is Fe.

### Embodiment 19

The method of Embodiment 18, wherein the second compound is ferrocene (Fe(Cp)₂).

### Embodiment 20

The method of any one of Embodiments 1 to 19, wherein the oxidizing agent is ozone.

### Embodiment 21

The method of any one of Embodiments 1 to 20, wherein the annealing is performed by increasing the temperature at a rate in a range of from about 3° C. per minute to about 400° C. per minute.

### Embodiment 22

The method of any one of Embodiments 1 to 21, wherein the annealing is performed at temperature of about 100° C. to 900° C.

### Embodiment 23

The method of any one of Embodiments 1 to 22, wherein the first substrate comprises a perovskite.

### Embodiment 24

The method of Embodiment 23, wherein the perovskite comprises SrTiO₃, LaTiO₃, LaAlO₃, DyScO₃, GdScO₃, KTaO₃, (La,Sr)(Al,Ta)O₃, or a combination thereof.

### Embodiment 25

The method of Embodiment 23 or 24, wherein the first substrate comprises a perovskite that has previously been deposited on a non-perovskite surface, such as silicon.

### Embodiment 26

The method of any one of Embodiments 1 to 25, wherein the second substrate comprises Si/SiO₂.

### Embodiment 27

The method of any one of Embodiments 1 to 26, wherein at least some of the introducing steps are performed in alternation.

### Embodiment 28

The method of any one of Embodiments 1 to 27, wherein the amorphous film has an atomic ratio of first metal to second metal of about 1:1.

### Embodiment 29

The method of any one of Embodiments 1 to 28, wherein the annealing is performed using joule, radiant, convective, or a pulsed or steady state laser.

### Embodiment 30

The method of any one of Embodiments 1 to 29, wherein the annealing is performed in the presence of a poling electric field.

### EXAMPLES

The following examples, while illustrative individual embodiments, are not intended to limit the scope of the described invention, and the reader should not interpret them in this way. Further, the following non-limiting examples and descriptions refer to the specific use of atomic layer deposition to prepare hetero-epitaxial thin films of the perovskite multiferroic and visible band-gap photoferroelectric BiFeO₃(001) on SrTiO₃(001) with film quality comparable to high- and ultrahigh vacuum physical vapor and molecular beam epitaxial deposition are disclosed. This disclosure is illustrative only, provided to demonstrate the utility of the approached described herein, and does not limit the scope of the present application. That is, and as described above, descriptions of these materials may also provide relative supporting disclosures for other perovskite materials. Additional examples are also provided.

Facile low-temperature and low-vacuum deposition of an amorphous ternary oxide and its subsequent epitaxial crystallization by the methods disclosed result in uniform, phase-pure perovskite films with interfacial coherency of atomic planes opens the way for inexpensive and practical perovskite oxide-based thin film technologies.

### Example 1

Heteroepitaxial BiFeO₃ via ALD suitably uses precursors that (1) can adsorb on the surface and be oxidized to enable production of a ternary oxide in sequential cycles, (2) does not introduce other cations/anions (contamination) into the films and (3) have overlapping ALD temperature windows. Bi(mmp)₃ (tris(1-methoxy-2-methyl-2-propoxy)bismuth) is considered suitable, as it has a wide ALD temperature window (200-300° C.), high stability and contains only Bi and organic ligands. Bi(mmp)₃ was reported to have a first considerable weight loss in the temperature range of ˜130-170° C. due to the volatilization of the compound and the second weight loss after 170° C. attributed to the decomposition of Bi(mmp)₃.

According to these data, 135-145° C. was chosen as an evaporation temperature of Bi(mmp)₃, which provided sufficiently reproducible precursor pulses. For the deposition of iron oxide Fe(C₅H₅)₂ (ferrocene) was selected based on its thermal stability, small molecule size and can easily be oxidized by ozone. A suitable evaporation temperature for the ferrocene source was 90° C.

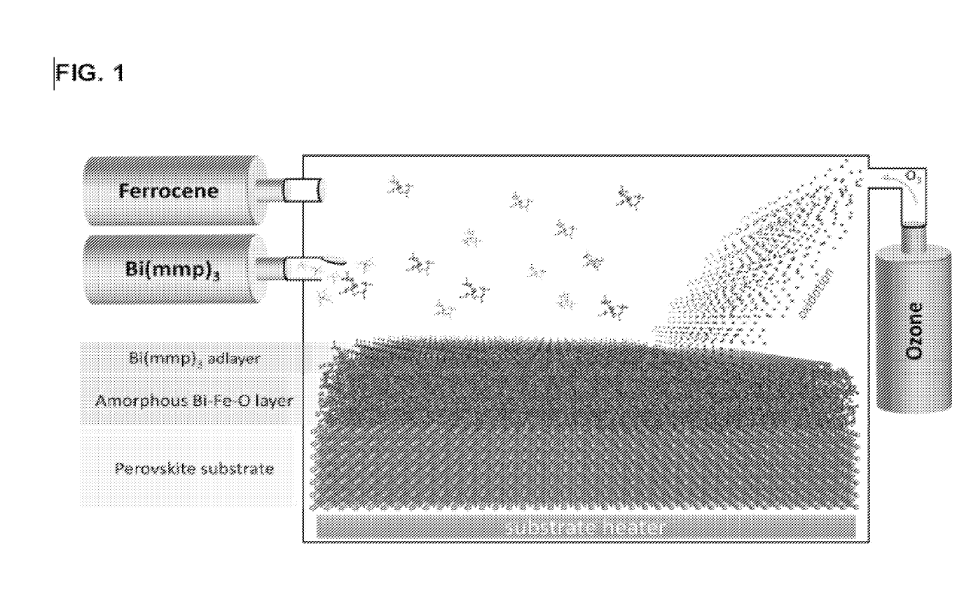

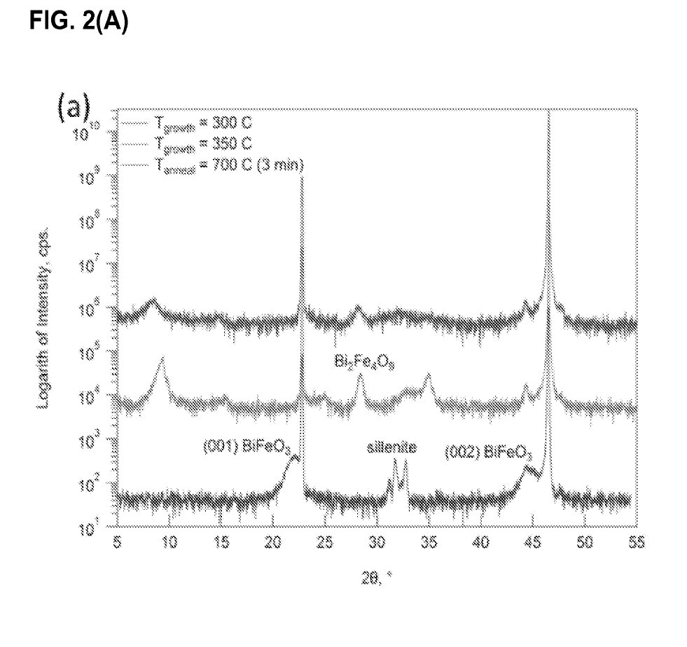

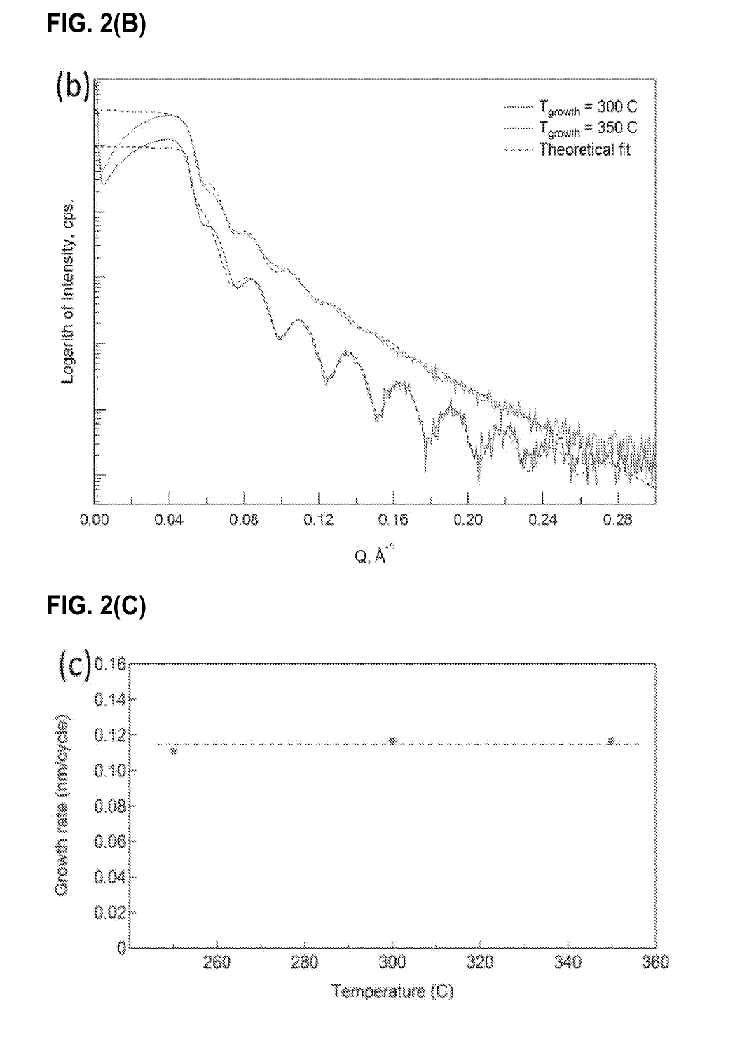

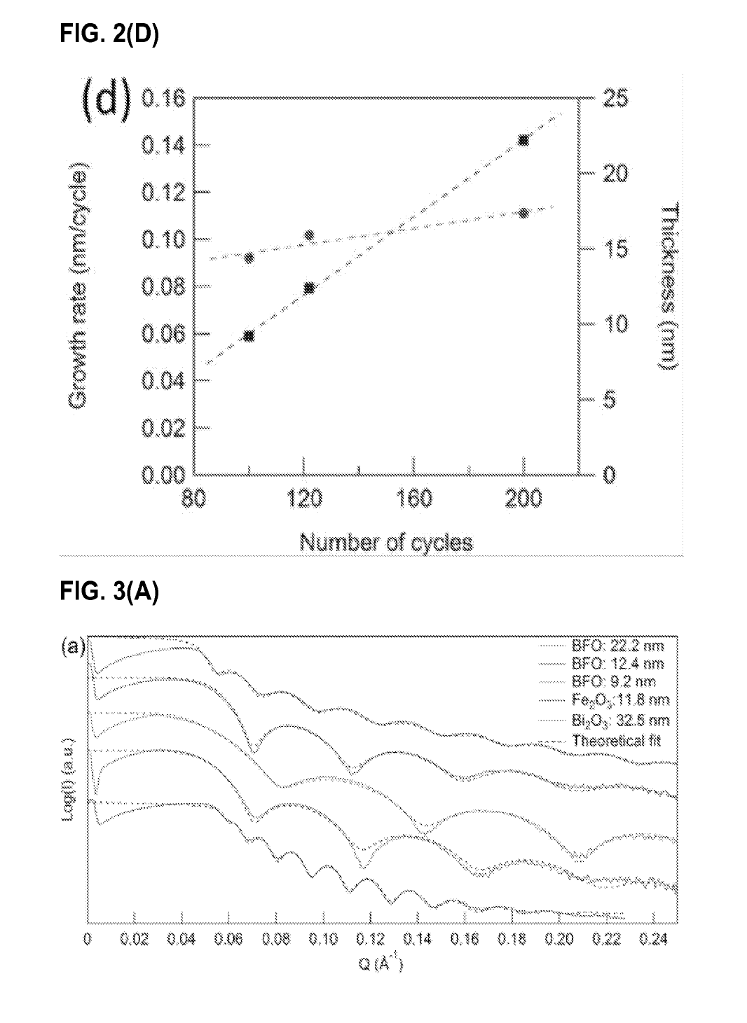

ALD experiments with ferrocene resulted in a stable growth of iron oxide at substrate temperatures in the range of 150-300° C. when ozone (ca. 20-30 vol. %) was used as an oxidizing agent. To obtain the film components for BiFeO₃ the substrate was heated to 250° C. and both precursors were sequentially delivered into the ALD reactor, as schematically illustrated in FIG. 1. The number of pulses for each precursor within each sub-cycle was minimized while maintaining the correct stoichiometry in the final Bi—Fe—O films. Bi(mmp)₃ showed a higher growth rate than Fe(C₅H₅)₂, thus the ratio between the number of pulses was N_{Fe}:N_{Bi}≈3-5. Each Bi—Fe—O thin film deposition run was carried out on both SiO₂/Si and SrTiO₃(001) simultaneously. Even in ALD-limited growth the thickness of a simple oxide film depended non-linearly on the number of cycles when the total number of cycles was small (typically less than 7-10), causing some variation in the film thickness from run to run. In these experiments, however, a constant growth rate of ˜0.12 nm/supercycle from 250-350° C. was observed (FIG. 2(C)).

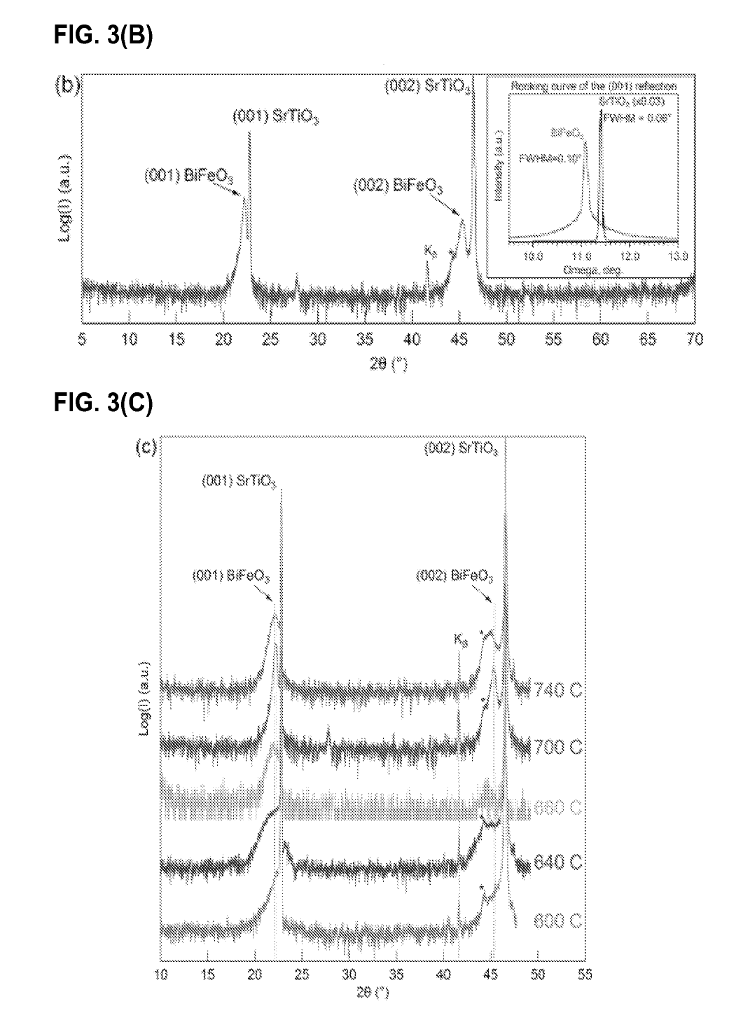

Typically, films obtained via ALD possessed atomic-scale roughness; in the illustrative studies presented here, the as-deposited individual Bi₂O₃ and Fe₂O₃ thin films showed roughness values of 1-10 Å over the whole sample area (5×5 mm₂) depending on the thickness of the films 146 (FIG. 3(A)), with Bi₂O₃ films usually having roughness of almost twice as much as Fe₂O₃.

For Bi—Fe—O thin films, the roughness was nearly atomic-scale (1-3 Å) as shown in the long oscillation “tails” in FIG. 3(A). X-ray diffraction (XRD) of the as-deposited films with an excess of Bi deposited at 250° C. showed the presence of a crystallized sillenite phase (FIG. 2), while an intentional excess of Fe did not produce any evidence of crystallization in the film. Some oxides are known to crystallize at low temperatures (˜200-300° C.) during the ALD process when strong oxidizing conditions are used, and pure bismuth oxide deposited using Bi(mmp)₃ turned about to be such a case. There appeared to be no convincing evidence of the BiFeO₃ phase recrystallization in as-deposited films.

One challenge of BiFeO₃ thin film synthesis by, e.g., pulsed laser deposition (PLD) or metal-organic chemical vapor deposition (MOCVD), is posed by a high partial vapor pressure of Bi₂O₃ at high temperatures which causes a gradual volatilization of Bi₂O₃ and consequent phase degradation. There are different ways of controlling Bi content in a film, both during deposition (e.g. by raising the initial Bi:Fe ratio) and after it (e.g. by isopiestic annealing). Because the Bi:Fe stoichiometry remains ˜1:1, however, BiFeO₃ crystallizes on the perovskite substrate. XRD of the annealed thin films (Tₐₙₙ=700° C.) revealed an epitaxial growth of BiFeO₃ on cubic perovskite substrates (FIG. 3(B)). In the inset of FIG. 3(B) a rocking curve for the (001) reflection of BiFeO₃ with respect to the substrate is shown. Excellent orientational growth and crystallinity of the film is manifested by a small full-width half-maximum (FWHM) of the film peak (Δω˜0.1°, being almost equal to that of the single-crystal substrate and demonstrating film quality comparable to that obtained via MOCVD and PLD.

The temperature of annealing was varied from 600° C. to 740° C. to investigate the transition from the amorphous Bi—Fe—O film to the crystalline BiFeO₃. A broad (001) reflection of BiFeO₃ can be observed for the samples annealed at 600° C. (FIG. 3(C)), but from XRD data “epitaxial crystallization” of the pure perovskite phase occurs greater than about 660° C. No changes in the samples were observed when the annealing was done for >3-5 min., confirming that even a short thermal annealing (about 3 min) is enough in most cases to cause crystallization in ALD-grown epitaxial thin films. Because the exemplary ALD process involves a sequential deposition of bismuth and iron oxide layers, the resulting amorphous film was well intermixed and a short exposure to high annealing temperature leads to the crystallization of epitaxial BiFeO₃.

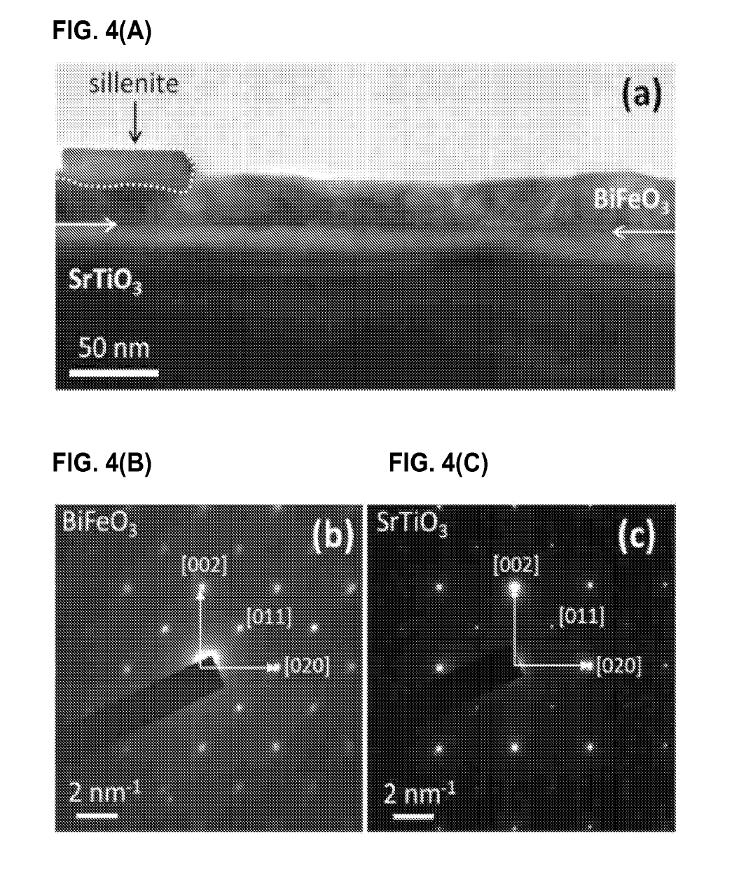

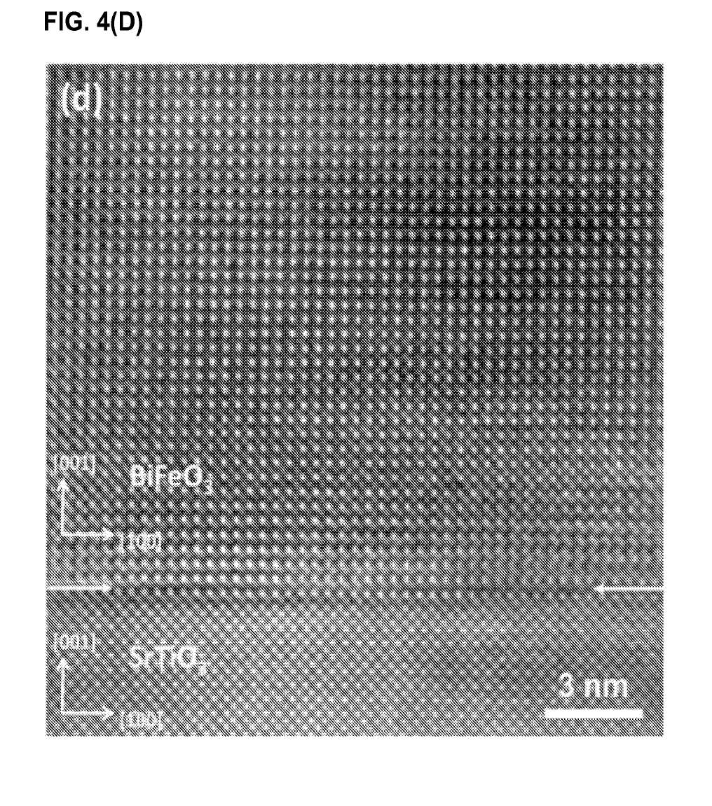

Transmission electron microscopy (TEM) (FIG. 4) revealed that the film consisted primarily of a perovskite phase with some nano-inclusions of the sillenite phase (such as Bi₂₆₋ₓFeₓO_{40-y}, which is related to γ-Bi₂O₃) presumably due to small composition deviation. In FIGS. 4(A,B) TEM images and selected-area electron diffraction patterns of the epitaxial BiFeO₃ thin film annealed at 700° C. are shown. The roughness of the films turned out to be induced mostly due to the occasional appearance of the secondary phase on the surface. Excellent crystalline quality of the BiFeO₃ film was observed on a large scale in the TEM cross-sections of the annealed samples. Usually ALD-prepared thin films are reported to be polycrystalline and rather rough after annealing, in some cases containing amorphous inclusions if incomplete crystallization occurs. The illustrative samples did not present any evidence of an amorphous phase, nor was there found any impurity orientation of BiFeO₃. According to TEM imaging, the BiFeO₃ phase did not form distinguishable islands, but rather appeared to be laterally continuous. Significantly, the interface between the film and the substrate was free of misfit dislocations (FIGS. 3(C-D)), suggesting an epitaxially strained state of the film at the interface due to a small lattice mismatch (∈=−1.4%). Due to the small change in lattice parameters between the pseudomorphic (strained) and relaxed BiFeO₃ layers, it was not possible to observed the boundary between the two layers of the film in the Fourier-filtered image (FIGS. 4(D,E))

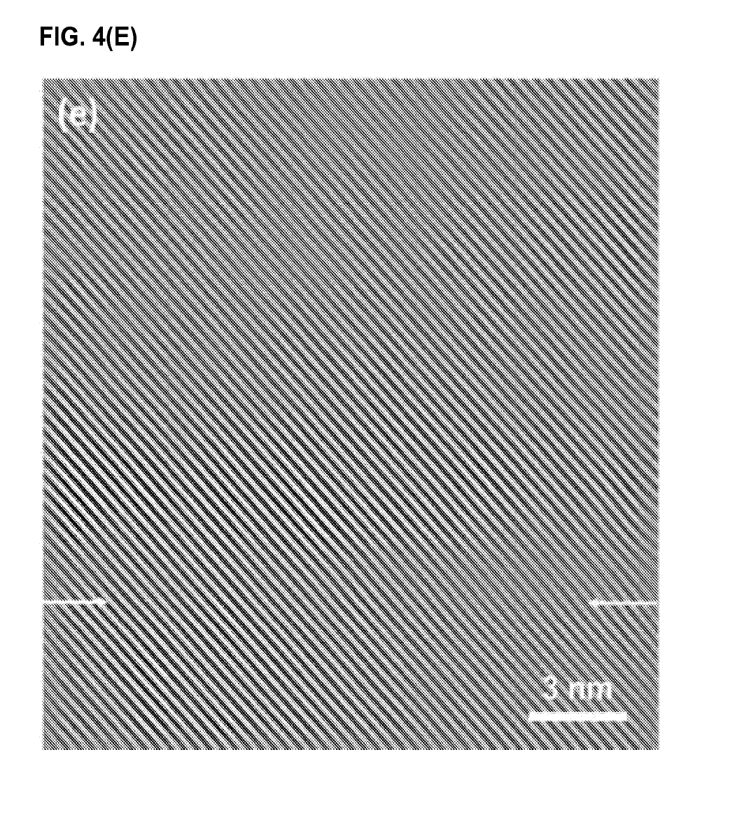

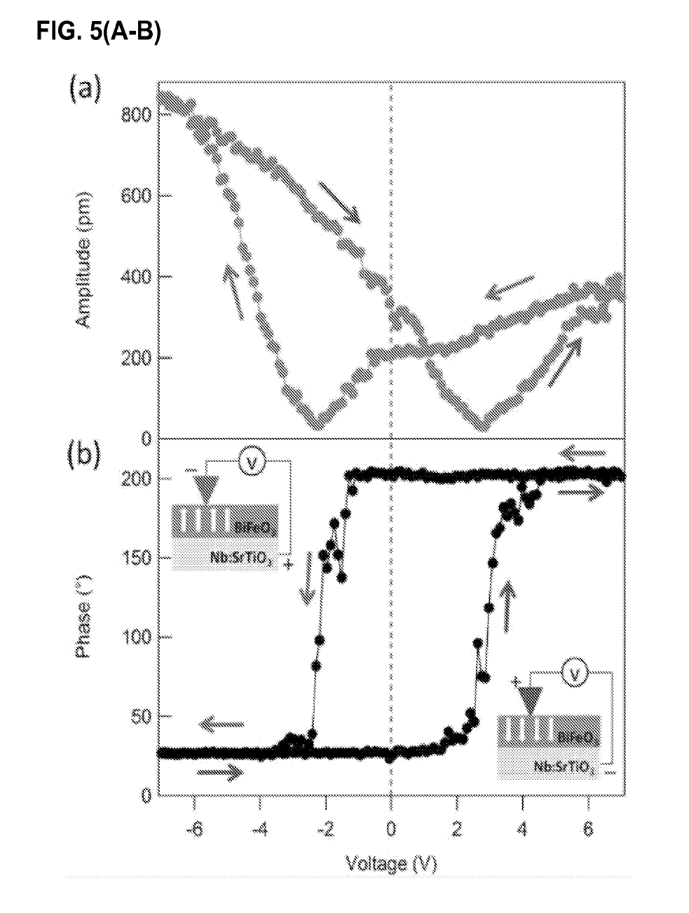

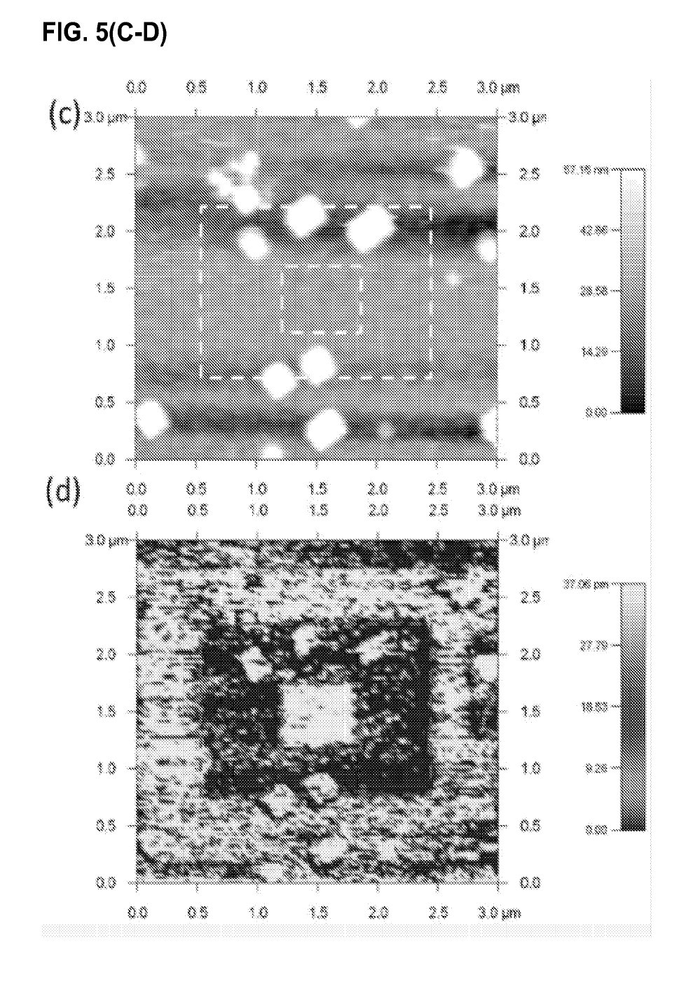

To probe ferroelectricity in our ALD-grown heteroepitaxial BiFeO₃ thin films, ALD was performed on the Bi—Fe—O system on Nb:SrTiO₃ (100), and the sample was annealed at 700° C. Hysteresis loops of the phase of the local ferroelectric piezoelectric signal obtained from the film (FIG. 5(A)) demonstrated a switching of ferroelectric polarization in ALD-grown BiFeO₃ thin films. A butterfly loop observed for piezoresponse amplitude (FIG. 5(B)) represented a typical behavior of local electromechanical coupling under switching bias. A metallic tip under switching bias was used to perform domain patterning of the BiFeO₃ film. The presence of sillenite cubes on the surface could be seen in the topographic height image, but the sillenite regions did not exhibit switched contrast following local poling of the film (FIGS. 5(C, D)). Hence, the ALD-grown BiFeO₃ thin films exhibited expected and desired ferroelectric properties.

Growth of thin-film BiFeO₃ is generally considered challenging due to Bi volatilization during deposition, leading to the appearance of parasitic phases in large quantities. The present process not only addressed this issue through a low temperature atomic layer deposition, but also enabled facile production of high-quality epitaxial thin films after a short thermal annealing. BiFeO₃ produced this way had a polarization value at least twice as much as that of Pb(Zr₁₋ₓTiₓ)O₃, which is currently used in ferroelectric random access memories (FeRAM), but its implementation in FeRAM architectures as a nanocapacitor is limited by the absence of a scalable deposition technique. ALD of BiFeO₃ can greatly improve the FeRAM density and allow for different 3D capacitor architectures to be made. Such capacitor architectures thus prepared are considered within the scope of the invention(s). Using the disclosed methods, ALD is now competitive with existing high-vacuum thin-film deposition methods in attaining high-quality heteroepitaxial perovskite oxides for multifunctional thin film science and technology particularly where a combination of atomic layer precision, easy control of volatile components, scalability and cost, and with the versatility of a conformal deposition associated with this surface reaction-rate limiting deposition process are important considerations.

### Example 2

### Experimental Sample Preparation

Thin Films of Bi—Fe—O and individual BiOₓ and FeOₓ were grown by ALD on SrTiO₃(001), Nb:SrTiO₃(001) (0.7 w. %) substrates (MTI Corp.) and SiO₂(10 nm)/Si(001) wafers using a commercial ALD reactor (Cambridge Nanotech Savannah 100). Fe(Cp)₂ (ferrocene, Sigma-Aldrich F408) and Bi(mmp)₃ (tris(1-methoxy-2-methyl-2-propoxy)bismuth, Strem) were used as volatile precursors and were heated to 90° C. and 135-145° C., respectively, providing enough vapor pressure for the deposition. Ozone (O₃) was used as an oxidizing agent. The gas inlet lines which transport precursors were kept at 150° C. The substrate was placed ˜3 cm from the gas inlet and the chamber was heated uniformly to 250° C. The gas outlet line was kept at 100-150° C. Annealing of as-grown amorphous films was performed in air at atmospheric pressure in a sealed oven with the step of 3-5° C./min during heating and 5° C./min during cooling of the samples. Annealing of the Bi—Fe—O thin films was carried out with the surface exposed to air and alternately, capped with an atomically smooth film of the sample composition that reduces the loss of Bi in the films. In the latter case, the deposition of thin films with Bi:Fe1:1 was carried out on two substrates the cubic perovskite substrate and Si wafer. The film side of an SrTiO₃ substrate was put on the film side of a Si wafer, thus making a straight contact between the two films. The annealing was performed in air in a closed furnace. These conditions, which produce high-quality heteroepitaxial BiFeO₃ films, were chosen in order to restrict Bi₂O₃ to move only in two dimensions when the two atomically smooth films face each other, which is expected considerably suppress the loss of Bi in the films.

### Example 3

### Characterization and Analysis

Compositional analysis was collected within a dual-beam scanning electron-focused ion beam microscope (FEI Strata DB235) equipped with an X-ray fluorescence (XRF) spectroscopy source and detector (iXRF), and within an electron microscope (Zeiss Supra 50VP) equipped with an energy-dispersive X-ray spectroscopy (EDS) system. Thin film structure and thickness were analyzed using X-ray diffraction (XRD) and X-ray reflectivity (XRR) of thin film samples, collected in a 4-circle X-ray diffractometer (Rigaku Smartlab and Bruker D8 Advance, 40 kV, 44 mA, Cu Kβ) equipped with a double (220) Ge monochromator in a parallel beam geometry. Fitting of XRR data was performed using Motofit analysis package. Sample preparation for transmission electron microscopy (TEM) was done by mechanical polishing and ion milling (Fishione 1010 Low-angle ion mill) and bright-field imaging was performed using TEM (JEOL JEM2100) operated at 200 kV. Fourier filtering of the TEM images was done using Gatan DigitalMicrograph software; Wiener filtering was done using a script “HRTEM filters” written by D. R. G. Mitchell. Topographic height, local ferroelectric piezoelectric hystereses and piezoresponse force microscopy (PFM) were collected using an atomic force microscope, the latter two data types collected using dual ac resonance tracking (DART™) as implemented on an atomic force microscope (Cypher and MFP-3D, Asylum Research/Oxford Instruments, Santa Barbara Calif.) using a Pt-coated cantilever (Olympus AC240™, nominal stiffness 2 N/m and DART frequency of ˜300 kHz). The presented phase and amplitude loops of the local ferroelectric piezoelectric signal represent an average of four full cycles, and are representative of phase switching and amplitude variation obtained in the film.

### Example 4

### Secondary Phases

In these experiments, the crystallization of secondary phases was observed when the composition deviated from stoichiometry. A sillenite phase (Bi₂₆₋ₓFeₓO_{40-y}) was observed when the film composition ratio Bi:Fe>1, which is in accordance with a phase diagram of the Bi₂O₃—Fe₂O₃ system. An XRD pattern (FIG. 2(A), bottom) was collected from the sample grown on SrTiO₃ at 250° C. and subsequently annealed in air at 700° C. for 3 min. On the XRD pattern, a (001) series of peaks corresponding to the epitaxial growth of BiFeO₃ was observed. A set of three peaks at 20 between 30° and 35° are reflections of the sillenite phase. Noteworthy, when the Bi:Fe ratio was between 1 and 1.2, the amount of sillenite phase after annealing was negligibly small (i.e. it could not be detected by XRD). This was due to the high volatilization of Bi₂O₃ compared to Fe₂O₃ during ex situ annealing. Even though the annealing was rather short (1-5 min., depending on the thickness), it seemed to be enough to drive some Bi₂O₃ out from the film and “correct” the stoichiometry to 1:1. Interestingly, some crystallization was observed when the growth temperature during ALD process was raised to 300° C. and then to 350° C. As can be seen from the damping of oscillations of the XRR curves (FIG. 2(B)) a higher growth temperature produces a rougher film. This tendency is often observed for ALD processes and is connected with a partial crystallization/grain formation that takes place on the film surface. Identical growth rates at 250-350° C. (˜0.12 nm/supercycle; FIG. 2(C) confirmed that the ALD temperature window was broad. The as-deposited films contained an obvious crystalline phase.

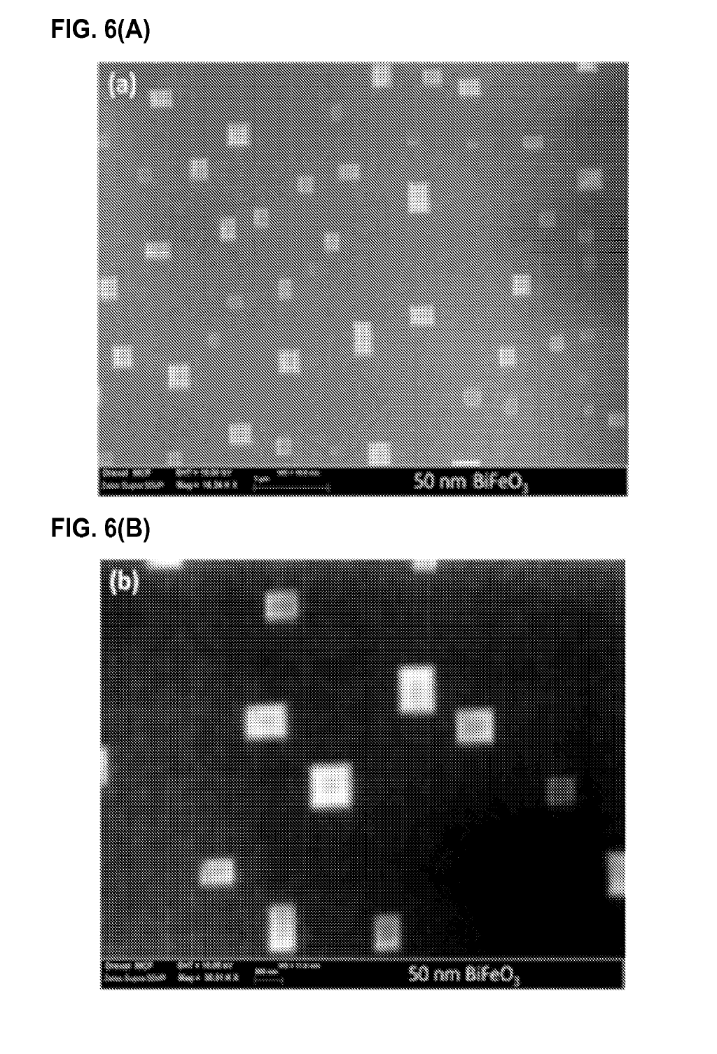

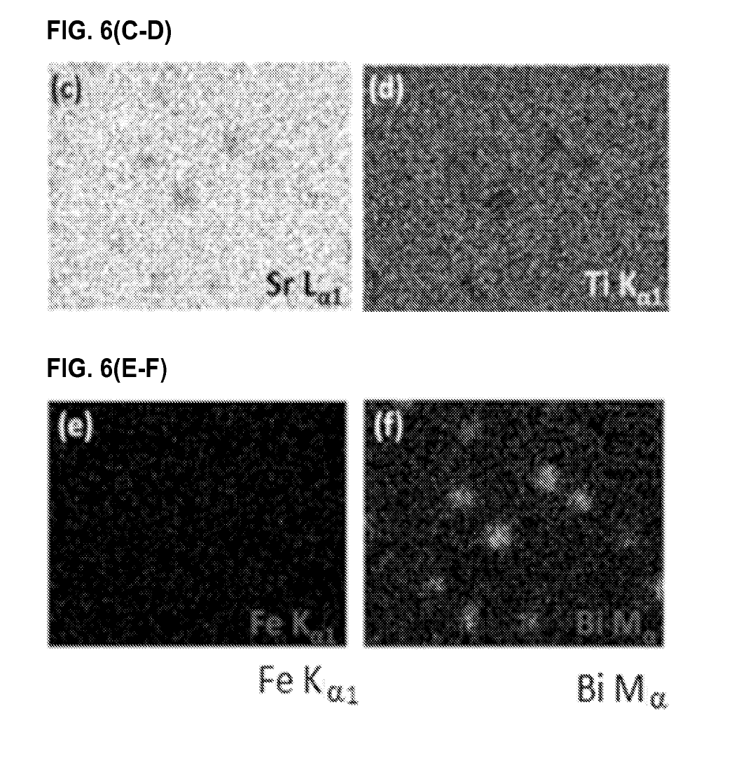

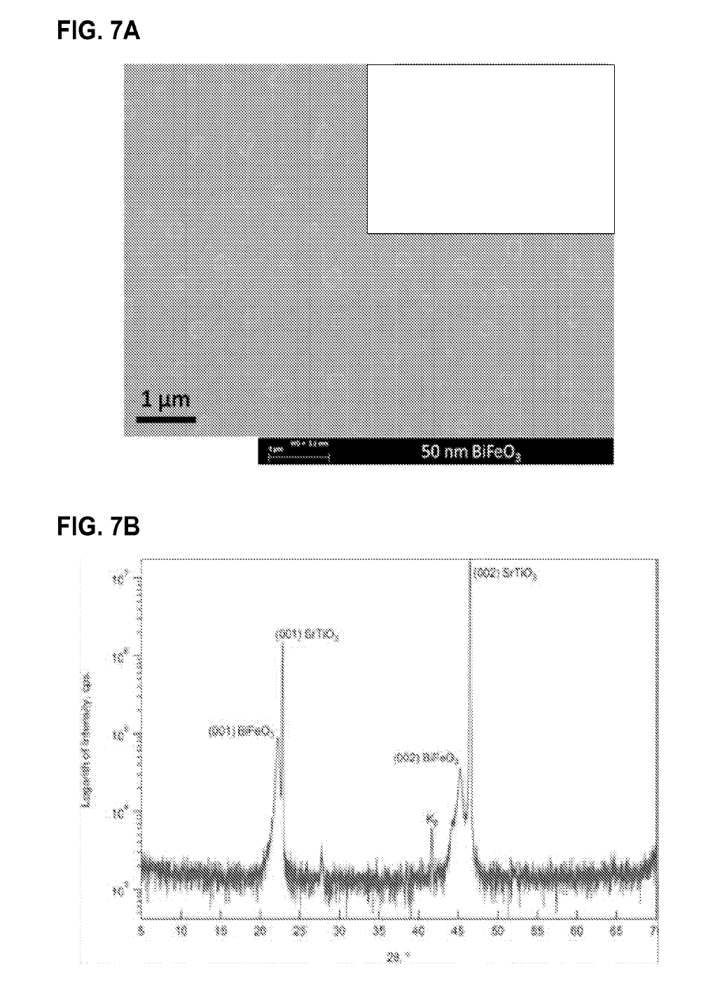

For the films deposited at 300° C. the broadening of the peaks on the XRD pattern was more pronounced than in the case of the deposition at 350° C. The latter in turn produced additional phases. Deposition of pure Bi₂O₃ and Fe₂O₃ films showed that Fe₂O₃ did not tend to crystallize when it was grown in these conditions (ferrocene oxidizes via ozone at T=200-350° C.), yet Bi₂O₃ showed crystallinity similarly to the secondary phases in as-deposited Bi—Fe—O thin films. Scanning electron microscopy (SEM) showed typical rectangular crystallites on the surface of annealed films (FIG. 6), which was not seen in the case of the pure-phase BiFeO₃ thin film (FIG. 7). Energy-dispersive X-ray spectroscopy was used in FIGS. 6(C-F) to show the composition of the cubes by performing high-resolution mapping of chemical elements. Signals of Ti Kα₁ and Sr Lα₁ edges were coming from the substrate and are shadowed in the regions with the cubes. A strong contrast in Bi M signal between the cubes and the surrounding film (compared to a homogeneous map of the Fe Kα₁ line) indicated that the cubes contained primarily Bi atoms. Without being bound to any particular theory, these admixture phases may have been mostly Bi₂O₃, possibly doped by Fe (and thus forming Bi₂₆₋ₓ FeₓO_{40-y}).

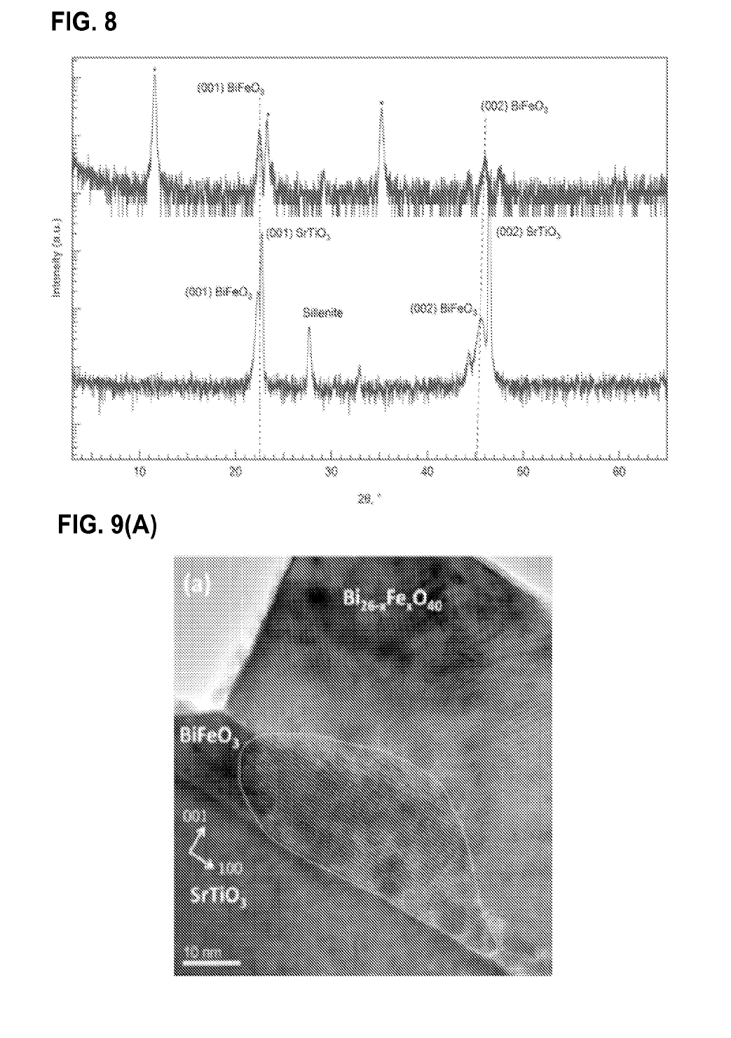

In FIG. 2(A), FIG. 3, and FIG. 8, one could see some distinct reflections at 2θ≈44.3° marked by an asterisk. This reflection was presumably caused by internal slight misalignment of the optical system of a diffractometer, since it was also observed for bare SrTiO₃ substrates, or from W Lα radiation known to come from the X-ray anode tube together with copper-related radiation. Due to a very high intensity of the (002) SrTiO₃ reflection it was possible to observe a very small Cu Kβ peak that was not damped completely by the monochromator used in the measurements.

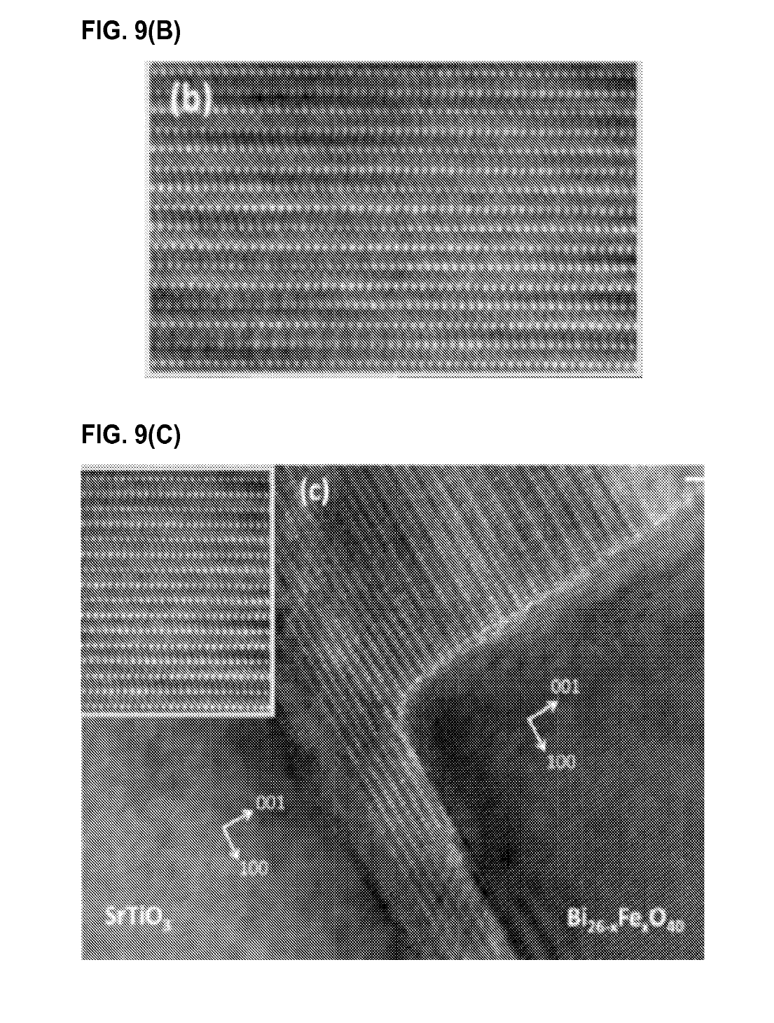

Shown in FIGS. 9(A-C) are TEM images of the sillenite phase that crystallized on BiFeO₃ and an unidentified phase. Sillenite usually grew epitaxially on both SrTiO₃ and BiFeO₃ in the “cube-on-cube way, as would be expected for this phase assembly. The unknown phase appeared occasionally in non-stoichiometric thin films in the form of small inclusions. XRD pattern of the non-stoichiometric film shown in FIGS. 9(A-C) is shown in FIG. 9(D): bismuth oxide with a very large unit cell parameter could be deduced from the data. However, the unknown secondary phase remained unidentified. This unknown phase also tended to appear whenever a Bi—Fe—O sample (with a slight stoichiometry deviation Bi:Fe>1) grown on SiO₂/Si(001) was annealed (FIG. 8). The growth of BiFeO₃ on SiO₂/Si wafers appeared to be oriented in the same way as for BiFeO₃/SrTiO₃ heterostructures.

Without being bound to the correctness of this theory, the unknown phase observed on the XRD pattern in FIG. 8 was presumably a phase of the Bi₂O₄₋ₓ (x<1) type, which was typically represented by its large unit (the first reflection comes from the planes with d=7.61 Å. Although the two samples, whose XRD patterns are known in FIG. 8, were annealed in a close contact with each other, this large-unit-cell phase was not observed on the SrTiO₃ substrate. Curiously, there are reflections with large d-spacing on the XRD patterns of as-deposited films (FIG. 2): the first peak corresponded to d≈9.64 Å which was larger than 7.61 Å observed for the annealed samples. This could mean that during annealing there should be a process of oxidation Bi⁺→Bi³+ in the Bi-rich phase that changes the unit cell parameter. In as-deposited films a peak at 28.44 θ (d≈3.13 Å corresponded to the Bi₂Fe₄O₉ phase, which was different from the peak in FIG. 8 related to sillenite (dₚₑₐₖ≈3.21 Å).

### Example 4

### Piezoresponse Force Microscopy

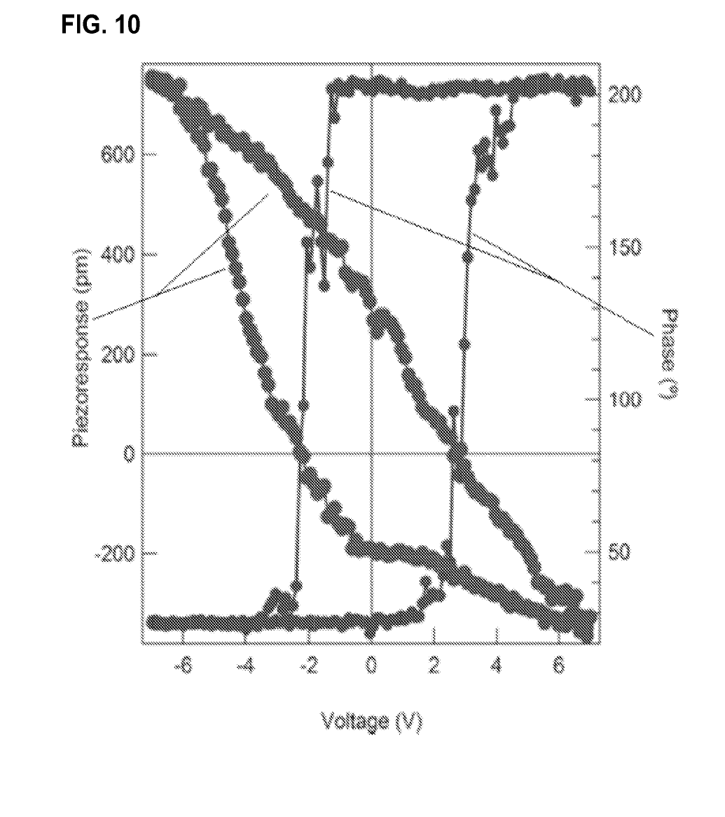

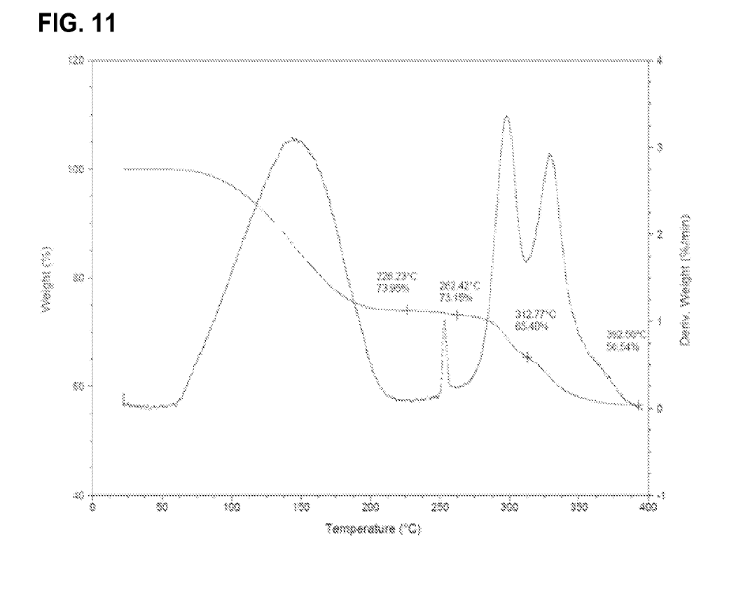

The piezoresponse (PR) was calculated by the formula PR=A cos(φ) and is depicted in FIG. 10 together with the phase. The presence of a hysteresis loop in the PR(V) provides further confirmation of a ferroelectric behavior of the sample because the PR is a property of the material studied rather than of the tip-surface system.

### Example 5

### Magnetic Properties

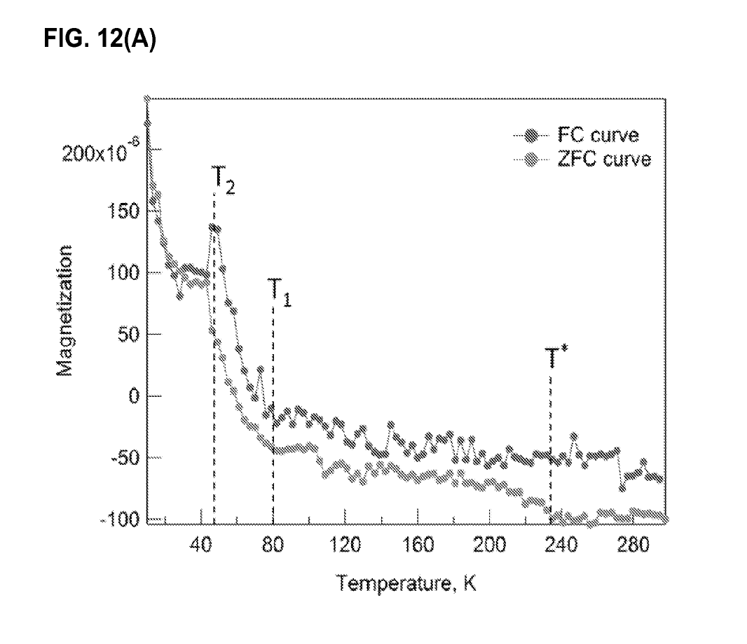

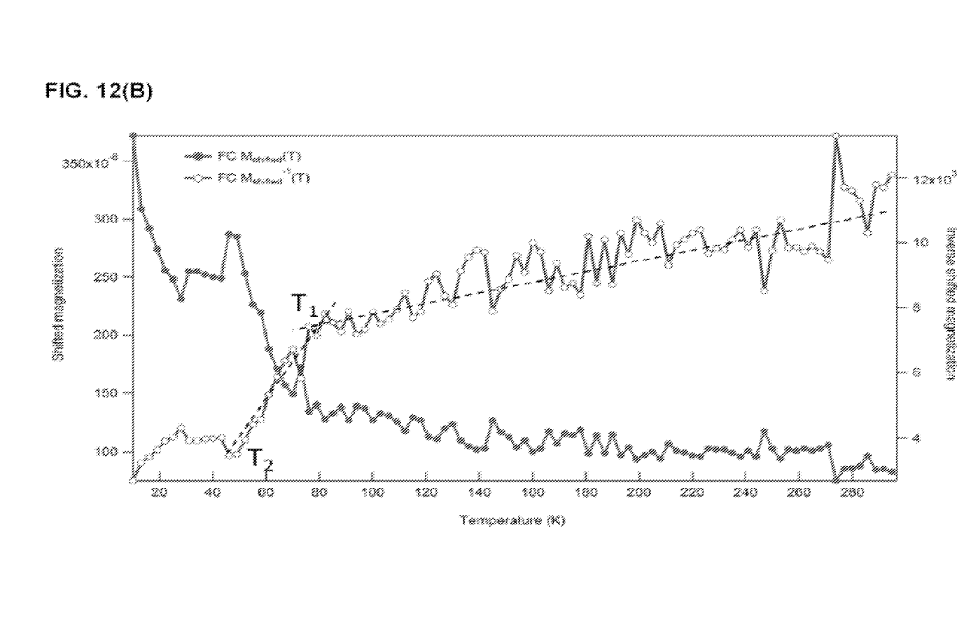

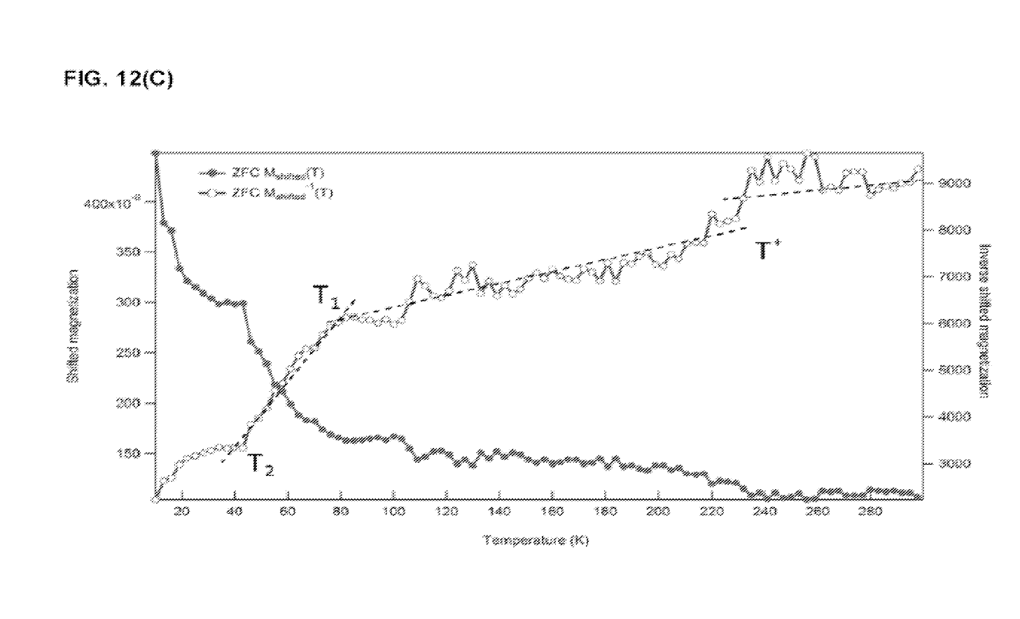

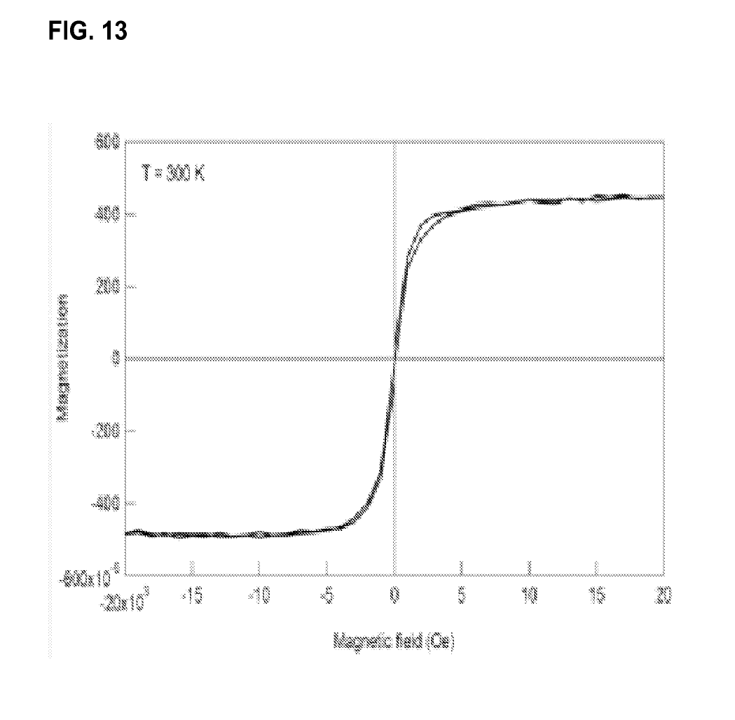

Some magnetic characteristics (including magnetic susceptibilities of the ALD-grown crystalline BiFeO₃ films, as described above, are shown in FIGS. 12 (A-C) and FIG. 13.

It is to be understood that while the invention has been described in conjunction with the preferred specific embodiments thereof, that the foregoing description and the examples that follow are intended to illustrate and not limit the scope of the invention. It will be understood by those skilled in the art that various changes may be made and equivalents may be substituted without departing from the scope of the invention, and further that other aspects, advantages and modifications will be apparent to those skilled in the art to which the invention pertains. In addition to the embodiments described herein, the present invention contemplates and claims those inventions resulting from the combination of features of the invention cited herein and those of the cited prior art references which complement the features of the present invention. Similarly, it will be appreciated that any described material, feature, or article may be used in combination with any other material, feature, or article, and such combinations are considered within the scope of this invention.

The disclosures of each patent, patent application, and publication cited or described in this document are hereby incorporated herein by reference, each in its entirety, for all purposes.

What is claimed:

1. A method for forming a perovskite film by atomic layer deposition, said method comprising:
(a) introducing a first compound comprising a first metal, an oxidizing agent, and a second compound comprising a second metal so as to form an amorphous layer comprising the first and second metals and an oxidizing agent on a first substrate; then
(b) covering at least a portion of the amorphous layer with a barrier that at least partially prevents the first metal, the second metal, oxygen atoms, or any combination thereof from being released during annealing; and then
(c) annealing the amorphous layer to form a perovskite film.

2. The method of claim 1, wherein the barrier comprises a second amorphous layer comprising the first and second metals and oxidizing agent.

3. The method of claim 1, wherein the annealing forms a single-crystalline perovskite film.

4. The method of claim 2, wherein the barrier further comprises a second substrate.

5. The method of claim 3, wherein the covering comprises contacting the second amorphous layer and the amorphous layer so as to give rise to an amorphous film comprising the first and second metals and oxidizing agent disposed between a first and second substrate.

6. The method of claim 1, the method comprising:
(a) introducing a first compound comprising a first metal, an oxidizing agent, and a second compound comprising a second metal onto a substrate, wherein the introduction is performed under sufficient conditions to form a first amorphous film comprising the first and second metals and oxidizing agent on the first substrate;
(b) covering substantially all of the first amorphous film with a barrier that prevents the first or second metal or any combination thereof from leaving the film under annealing; and
(c) annealing the first amorphous film to produce an epitaxial perovskite film.

7. The method of claim 5, wherein annealing the first amorphous film produces a hetero-epitaxial perovskite film.

8. The method of claim 5, wherein annealing the first amorphous film produces a single-crystalline hetero-epitaxial perovskite film.

9. The method of claim 5, wherein the barrier used in the covering step comprises a second amorphous film comprising the first metal, the second metal, and oxygen disposed on a second substrate.

10. The method of claim 6, wherein covering substantially all of the first amorphous film is performed by contacting the second amorphous film of the barrier to the first amorphous film.

11. The method of claim 1, wherein step (a) is repeated to produce at least two amorphous layers prior to effecting steps (b) and (c), wherein each application of step (a) introduces a different first compound and a second compound than the preceding step, or a different ratio of first compound and a second compound than the preceding step, such that each of the least two amorphous layers are compositionally different than the preceding layer.

12. The method of claim 11, wherein each of the at least two amorphous layers comprise the same first and second metals in differing proportions relative to the preceding film.

13. The method of claim 1, wherein steps (a) through (c) are repeated to produce at least two stacked perovskite films, wherein each application of steps (a) through (c) introduces a different first compound and a second compound than the preceding step, or a different ratio of first compound and a second compound than the preceding step, such that each of the least two perovskite are compositionally different than the preceding film.

14. The method of claim 13, wherein each of the at least two perovskite films comprise the same first and second metals in differing proportions relative to the preceding film.

15. The method of claim 13, wherein each of the at least two perovskite films have a different crystalline or polycrystalline structure than the preceding layer.

16. The method of claim 1 wherein the first metal is Bi.

17. The method of claim 16, wherein the first compound is (tris(1-methoxy-2-methyl-2-propoxy)bismuth) [Bi(mmp)₃]triphenylbismuth, tris(tris(2,2,6,6-tetramethyl-3,5-heptanedionate))bismuth (III) [Bi(thd)₃:], or Bi(acetate)₃.

18. The method of claim 1, wherein the second metal is Fe.

19. The method of claim 18, wherein the second compound is ferrocene (Fe(Cp)₂).

20. The method of claim 1, wherein the oxidizing agent is ozone.

21. The method of claim 1, wherein the annealing is performed by increasing the temperature at a rate in a range of from about 3° C. per minute to about 400° C. per minute.

22. The method of claim 1, wherein the annealing is performed at temperature of about 100° C. to 900° C.

23. The method of claim 1, wherein the first substrate comprises a perovskite.

24. The method of claim 23, wherein the perovskite comprises SrTiO₃, LaTiO₃, LaAlO₃, DyScO₃, GdScO₃, KTaO₃, (La,Sr)(Al,Ta)O₃, or a combination thereof.

25. The method of claim 23, wherein the first substrate comprises a perovskite that has previously been deposited on a non-perovskite surface.

26. The method of claim 1, wherein the second substrate comprises Si/SiO₂.

27. The method of claim 1, wherein at least some of the introducing steps are performed in alternation.

28. The method of claim 1, wherein the amorphous film has an atomic ratio of first metal to second metal of about 1:1.

29. The method of claim 1, wherein the annealing is performed using joule, radiant, convective, or a pulsed or steady state laser.

30. The method of claim 1, wherein the annealing is performed in the presence of a poling electric field.
